(19) United States
(12) Patent Application Publication
(10) Pub. No.: US 2021/0305150 A1
(43) Pub. Date: Sep. 30, 2021

(54) MEMORY DEVICE

(71) Applicant: SAMSUNG ELECTRONICS CO., LTD., SUWON-SI (KR)

(72) Inventors: KANGMIN KIM, HWASEONG-SI (KR); BEYOUNGHYUN KOH, SEOUL (KR); YONGJIN KWON, YONGIN-SI (KR); JOONGSHIK SHIN, YONGIN-SI (KR); GUNWOOK YOON, HWASEONG-SI (KR)

(21) Appl. No.: 17/032,100

(22) Filed: Sep. 25, 2020

(30) Foreign Application Priority Data
Mar. 26, 2020 (KR) 10-2020-0037060

(51) Int. Cl. H01L 23/528; H01L 27/11556; H01L 27/11529; H01L 27/11582; H01L 27/11573; H01L 23/00

(52) U.S. Cl. CPC H01L 23/528; H01L 27/11556; H01L 23/562; H01L 27/11582; H01L 27/11573; H01L 27/11529

(57) ABSTRACT

A memory device including a substrate; a lower conductive layer on the substrate; a stacked structure including gate layers and interlayer insulating layers alternately stacked on the lower conductive layer; a channel structure in a channel hole that penetrates the stacked structure in a vertical direction; and a common source line structure in a common source line trench that penetrates the lower conductive layer and the stacked structure in the vertical direction. The common source line structure includes a side insulating layer on a side surface of the common source line trench, a central insulating layer at a central portion of the common source line trench, an intermediate conductive layer between the side insulating layer and the central insulating layer, and an upper conductive layer at an upper portion of the common source line trench.

### CROSS-REFERENCE TO RELATED APPLICATION

A claim of priority under 35 U.S.C. § 119 is made to Korean Patent Application No. 10-2020-0037060, filed on Mar. 26, 2020 in the Korean Intellectual Property Office, the entirety of which is hereby incorporated by reference.

### BACKGROUND

The present disclosure relates to memory devices, and more particularly to vertical non-volatile memory devices.

With the continued demand for multi-functional, high performance, and miniaturized information communication devices, there has been a need for memory devices having increased capacity and integration. According to this trend, vertical non-volatile memory devices including a plurality of gate layers stacked on a substrate with a channel structure penetrating the plurality of gate layers in a vertical direction have been developed. In such vertical nonvolatile memory devices, memory capacity may be increased by increasing the number of gate layers stacked on the substrate. Thus, through the use of vertical non-volatile memory devices increased storage capacity and integration may be realized.

### SUMMARY

Embodiments of the inventive concepts provide a highly integrated memory device having reduced warpage and reduced noise.

Embodiments of the inventive concepts provide a memory device including a substrate; a lower conductive layer on the substrate; a stacked structure on the lower conductive layer, the stacked structure including gate layers and interlayer insulating layers alternately stacked on the lower conductive layer; a channel structure in a channel hole that penetrates the stacked structure in a vertical direction; and a common source line structure in a common source line trench that penetrates the lower conductive layer and the stacked structure in the vertical direction. The common source line structure includes a side insulating layer on a side surface of the common source line trench, a central insulating layer at a central portion of the common source line trench, an intermediate conductive layer between the side insulating layer and the central insulating layer, and an upper conductive layer at an upper portion of the common source line trench.

Embodiments of the inventive concepts further provide a memory device including a substrate; a lower conductive layer on the substrate; a stacked structure on the lower conductive layer, the stacked structure including gate layers and intermediate insulating layers alternately stacked on the lower conductive layer; a channel structure inside a channel hole that penetrates the lower conductive layer and the stacked structure in a vertical direction; and a common source line structure in a common source line trench that penetrates the stacked structure in the vertical direction. The common source line structure includes a side insulating layer on a side surface of the common source line trench, a central insulating layer at a center portion of the common source line trench, an intermediate conductive layer between the side insulating layer and the central insulating layer, and an upper conductive layer at an upper portion of the common source line trench. The intermediate conductive layer contacts the lower conductive layer.

Embodiments of the inventive concepts still further provide a memory device including a lower structure; and an upper structure on the lower structure. The lower structure includes a substrate, a peripheral circuit on the substrate, and a first pad connected to the peripheral circuit. The upper structure includes a stacked structure including gate layers and intermediate insulating layers alternately stacked in a vertical direction, a channel structure that penetrates the stacked structure in the vertical direction, a common source line structure that penetrates the stacked structure in the vertical direction, and a second pad connected to the common source line structure. The common source line structure includes a central insulating layer, an intermediate conductive layer on a side surface of the central insulating layer, a side insulating layer on a side surface of the intermediate conductive layer, and an upper conductive layer on an upper end of the central insulating layer. The upper structure contacts the lower structure, and the second pad contacts the first pad.

Embodiments of the inventive concepts also provide a memory device including a substrate; a lower conductive layer on the substrate; a stacked structure on the lower conductive layer, the stacked structure including gate layers and interlayer insulating layers alternately stacked on the lower conductive layer; a channel structure in a channel hole that penetrates the stacked structure in a vertical direction, the channel structure extending into the substrate; and a common source line structure in a common source line trench that penetrates the stacked structure in the vertical direction. The common source line structure includes a side insulating layer on a side surface of the common source line trench, a central insulating layer at a central portion of the common source line trench, an intermediate conductive layer between the side insulating layer and the central insulating layer, and an upper conductive layer at an upper portion of the common source line trench. The intermediate conductive layer electrically contacts the substrate.

### BRIEF DESCRIPTION OF THE DRAWINGS

Embodiments of the inventive concepts will be more clearly understood from the following detailed description taken in conjunction with the accompanying drawings in which:

FIG. 1 illustrates a schematic block diagram of a memory device according to embodiments of the inventive concepts;

FIG. 2 illustrates a schematic circuit diagram of one of the memory blocks included in a memory cell array of a memory device, according to embodiments of the inventive concepts;

FIG. 3 illustrates a schematic plan view of a memory device according to embodiments of the inventive concepts;

FIG. 4A illustrates a schematic cross-sectional view of a memory device taken along line A-A′ in FIG. 3, according to embodiments of the inventive concepts;

FIG. 4B illustrates an enlarged view of region A in FIG. 4A;

FIG. 5 illustrates a schematic cross-sectional view of a memory device according to embodiments of the inventive concepts;

FIG. 6 illustrates a schematic cross-sectional view of a memory device according to embodiments of the inventive concepts;

FIG. 7 illustrates an enlarged view of region B in FIG. 6;

FIG. 8 illustrates an enlarged view of a variation example of region B in FIG. 6;

FIG. 9 illustrates an enlarged view of a further variation example of region B in FIG. 6;

FIG. 10 illustrates a schematic cross-sectional view of a memory device according to embodiments of the inventive concepts;

FIG. 11 illustrates a schematic cross-sectional view of a memory device according to embodiments of the inventive concepts;

FIG. 12 illustrates a schematic cross-sectional view of a memory device according to embodiments of the inventive concepts;

FIG. 13 illustrates a schematic cross-sectional view of a memory device according to embodiments of the inventive concepts;

FIG. 14 illustrates a schematic cross-sectional view of a memory device according to embodiments of the inventive concepts;

FIG. 15 illustrates a schematic cross-sectional view of a memory device according to embodiments of the inventive concepts;

FIGS. 16A, 16B, 16C, 16D, 16E, 16F, 16G, 16H, 16I, 16J, 16K, 16L, 16M, 16N, 16O, 16P, 16Q and 16R illustrate schematic cross-sectional views descriptive of a manufacturing method of a memory device, according to embodiments of the inventive concepts; and

FIGS. 17A, 17B, 17C, 17D, 17E, 17F, 17G, 17H, 17I, 17J, 17K and 17L illustrate schematic cross-sectional views descriptive of a manufacturing method of a memory device, according to embodiments of the inventive concepts.

### DETAILED DESCRIPTION OF THE EMBODIMENTS

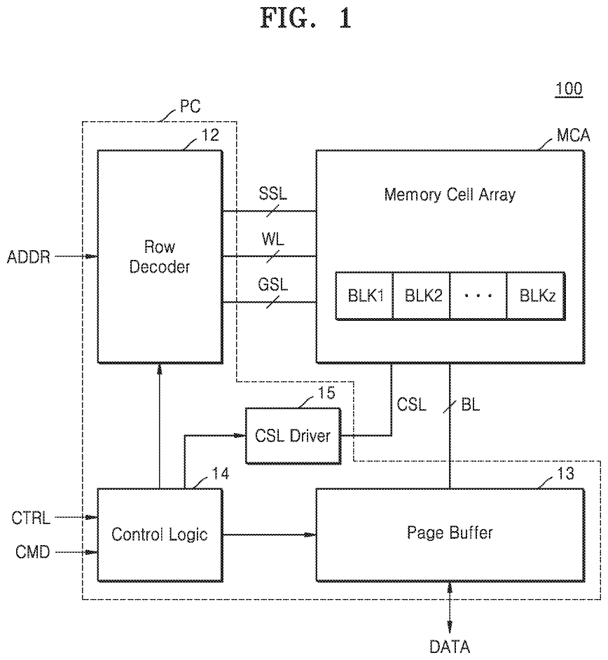

FIG. 1 illustrates a schematic circuit diagram of a memory device 100 according to embodiments of the inventive concepts.

Referring to FIG. 1, the memory device 100 may include a memory cell array MCA and a peripheral circuit PC. The peripheral circuit PC may include a row decoder 12, a page buffer 13, a control logic (e.g., circuit) 14 and a common source line (CSL) driver 15.

The memory cell array MCA may include first through z^{th} memory blocks BLK1 through BLKz (wherein z is an integer of 2 or more). Each of the first through z^{th} memory blocks BLK1 through BLKz (i.e., BLK1, BLK2, . . . BLKz) may include a plurality of memory cells capable of storing data. Each of the first through z^{th} memory blocks BLK1 through BLKz may include non-volatile memory cells that maintain stored data even when supply power is cut off. For example, each of the first through z^{th} memory blocks BLK1 through BLKz may include a flash memory cell.

The row decoder 12 may be connected to the memory cell array MCA via a plurality of string select lines SSL, a plurality of word lines WL, and a plurality of ground select lines GSL. The row decoder 12 may select at least one of the first through z^{th} memory blocks BLK1 through BLKz of the memory cell array MCA in response to an address ADDR provided by a memory controller (not illustrated). The row decoder 12 may select at least one of the word lines WL, the string select lines SSL, and the ground select lines GSL of a memory block that is selected in response to the address ADDR provided by a memory controller (not illustrated).

The page buffer 13 may be connected to the memory cell array MCA via a plurality of bit lines BL. The page buffer 13 may select at least one of the plurality of bit lines BL. The page buffer 13 may store data DATA received from a memory controller (not illustrated) in the memory cell array MCA. In addition, the page buffer 13 may output data DATA read from the memory cell array MCA to a memory controller (not illustrated).

The common source line driver 15 may be connected to the memory cell array MCA via the common source line CSL. The common source line driver 15 may ground the common source line CSL or apply a voltage to the common source line CSL.

The control logic 14 may control all operations of the memory device 100. The control logic 14 may control operations of the row decoder 12, the page buffer 13, and the common source line driver 15. For example, the control logic 14 may control the memory device 100 to perform a memory operation corresponding to a command CMD provided by a memory controller (not illustrated). In addition, the control logic 14 may generate various internal control signals used in the memory device 100 in response to a control signal CTRL provided by a memory controller (not illustrated).

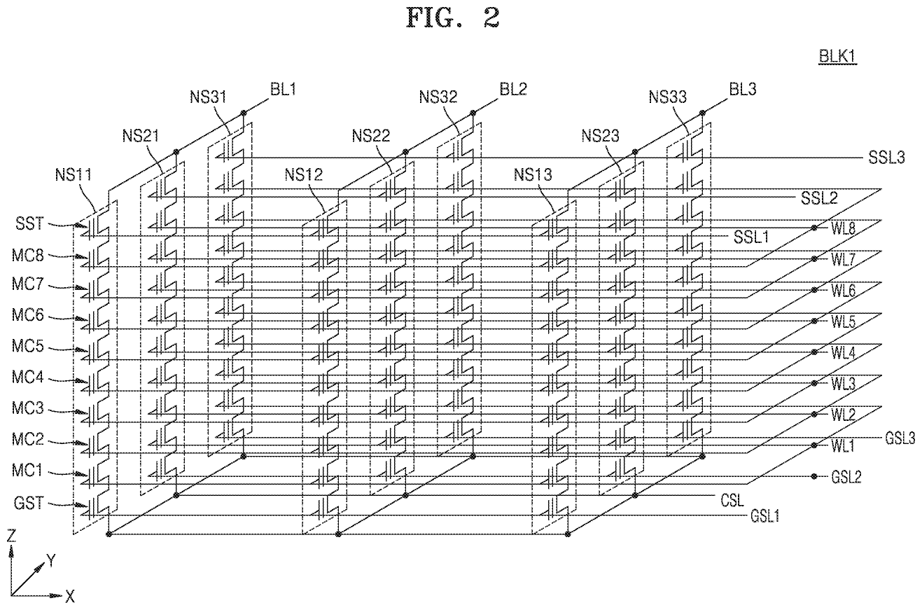

FIG. 2 illustrates a schematic circuit diagram of a first block BLK1 that is one of the memory blocks included in the memory cell array MCA (refer to FIG. 1) included in the memory device 100 (refer to FIG. 1), according to embodiments of the inventive concepts.

Referring to FIG. 2, the first memory block BLK1 may include NAND strings NS11 through NS13 (i.e., NS11, NS12 and NS13), NS21 through NS23 (i.e., NS21, NS22 and NS23), and NS31 through NS33 (i.e., NS31, NS32 and NS33). FIG. 2 illustrates that one first memory block BLK1 includes nine NAND strings NS11 through NS13, NS21 through NS23, and NS31 through NS33, but the number of NAND strings included in the first memory block BLK1 is not limited thereto. Each of the NAND string NS11 through NS13, NS21 through NS23, and NS31 through NS33 may include at least one string select transistor SST connected in series, first through eighth memory cells MC1 through MC8 (i.e., MC1, MC2, MC3, MC4, MC5, MC6, MC7 and MC8), and at least one ground select transistor GST. In FIG. 2, each of the NAND strings NS11 through NS13, NS21 through NS23, and NS31 through NS33 may include one string select transistor SST, eight memory cells MC1 through MC8, and one ground select transistor GST. However, the number of string select transistors SST, memory cells MC, and ground select transistors GST included in one of the NAND string NS11 through NS13, NS21 through NS23, and NS31 through NS33 is not limited thereto.

The NAND strings NS11 through NS13, NS21 through NS23, and NS31 through NS33 may be connected between first through third bit lines BL1 through BL3 (i.e., BL1, BL2 and BL3) and the common source line CSL. Gates of the string select transistors SST may be connected to first through third string select lines SSL1 through SSL3 (i.e., SSL1, SSL2 and SSL3). Gates of the first through eighth memory cells MC1 through MC8 may be connected to first through eighth word lines WL1 through WL8 (i.e., WL1, WL2, WL3, WL4, WL5, WL6, WL7 and WL8). Gates of the ground select transistors GST may be connected to first through third ground select lines GSL1 through GSL3 (i.e., GL1, GL2 and GL3). The common source line CSL may be commonly connected to the NAND strings NS11 through NS13, NS21 through NS23, and NS31 through NS33.

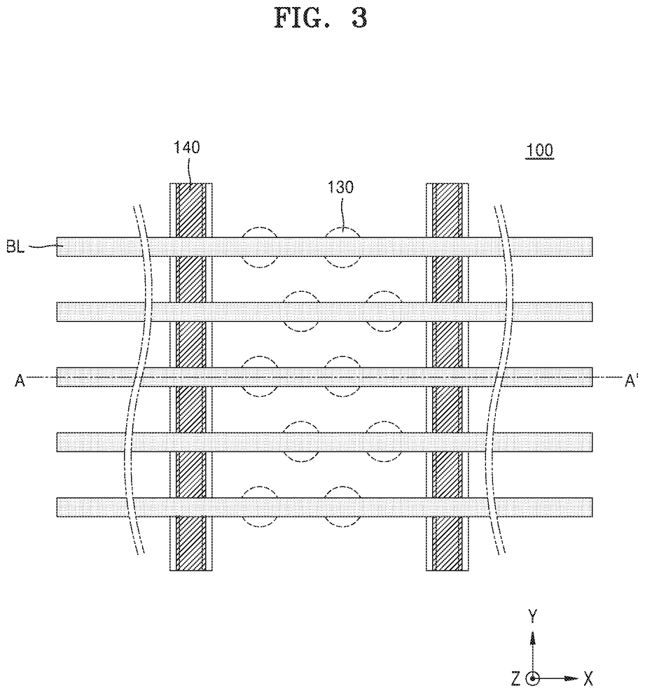

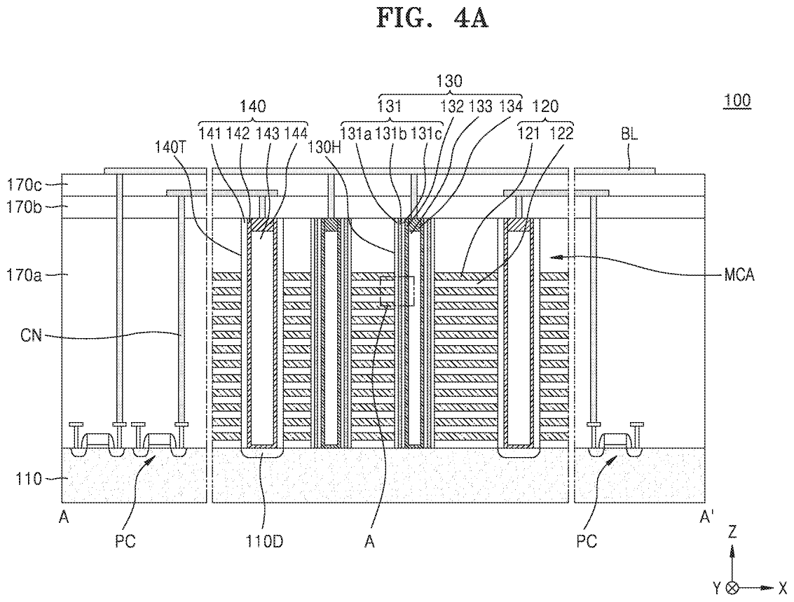

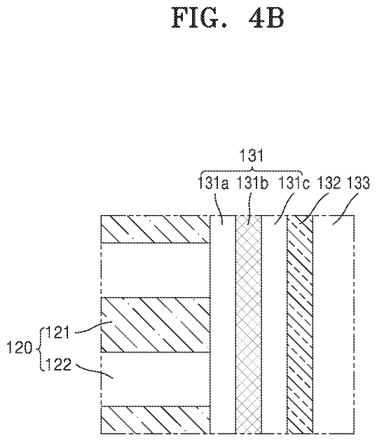

FIG. 3 illustrates a schematic plan view of a memory device 100 according to embodiments of the inventive concepts. FIG. 4A illustrates a schematic cross-sectional view of the memory device 100 taken along line A-A′ in FIG. 3, according to embodiments of the inventive concepts. FIG. 4B illustrates an enlarged view of a region A in FIG. 4A.

Referring to FIGS. 3, 4A, and 4B, the memory device 100 may include a substrate 110, the memory cell array MCA on the substrate 110, the peripheral circuit PC on the substrate 110, and a common source line structure 140 connecting between the memory cell array MCA and the peripheral circuit PC, and the bit line BL connecting between the memory cell array MCA and the peripheral circuit PC.

The substrate 110 may include a semiconductor material such as a Group IV semiconductor material, a Group III-V semiconductor material, and a Group II-VI semiconductor material. The Group IV semiconductor material may include, for example, silicon (Si), germanium (Ge), or Si—Ge. The Group III-V semiconductor material may include, for example, gallium arsenide (GaAs), indium phosphorus (InP), gallium phosphorus (GaP), indium arsenic (InAs), indium antimony (InSb), or indium gallium arsenide (InGaAs). The Group II-VI semiconductor material may include, for example, zinc telluride (ZnTe), or cadmium sulfide (CdS). The substrate 110 may include a bulk wafer or an epitaxial layer. The substrate 110 may include an impurity region 110D.

The memory cell array MCA may include a stacked structure 120 on the substrate 110 and a channel structure 130 penetrating the stacked structure 120.

The stacked structure 120 may include a plurality of gate layers 121 and a plurality of interlayer insulating layers 122 that are alternately stacked on the substrate 110 in a vertical direction (Z direction). In other words, the plurality of gate layers 121 may be spaced apart from each other by the interlayer insulating layers 122. For example, an interlayer insulating layer 122 is disposed between a pair of gate layers 121. Each gate layer 121 may for example include a conductive material including, but not limited to, tungsten (W), copper (Cu), silver (Ag), gold (Au), aluminum (Al), or a combination thereof. In some embodiments, each gate layer 121 may include titanium (Ti), tantalum (Ta), titanium nitride (TiN), tantalum nitride (TaN), or a combination thereof to prevent the conductive material from diffusing into the interlayer insulating layer 122 around each gate layer 121, but may further include a barrier material that is not limited thereto. Each interlayer insulating layer 122 may include an insulating material including, for example, silicon oxide, silicon nitride, a low-K material, or combinations thereof. The low-K material may be a material having a lower dielectric constant than silicon oxide, and may include, for example, phosphosilicate glass (PSG), borophosphosilicate glass (BPSG), fluorosilicate glass (FSG), organosilicate glass (OSG), spin-on-glass (SOG), spin-on-polymer, or a combination thereof.

The channel structure 130 may be inside a channel hole 130H penetrating the stacked structure 120 in the vertical direction (Z direction). The channel structure 130 may extend in the vertical direction (Z direction) and penetrate the stacked structure 120 in the vertical direction (Z direction). It should be here understood that the expression that a component penetrates or extends in the vertical direction (Z direction) means that the component penetrates or extends generally or approximately in the vertical direction (Z direction), but does not mean that the component necessarily and completely or perfectly penetrates or extends in the vertical direction (Z direction). For example, some of the components may penetrate or extend obliquely with respect to the vertical direction (Z direction). In addition, a direction in which the component generally penetrates or extends may be about 0 degrees to about 10 degrees with respect to the vertical direction (Z direction).

In some embodiments, the channel structure 130 may include a gate insulating layer 131 on the side of the channel hole 130H, a filling insulating layer 133 at the center of the channel hole 130H, and a channel layer 132 between the gate insulating layer 131 and the filling insulating layer 133, and a pad layer 134 at an upper portion of the channel hole 130H. In other words, the channel structure 130 may include the filling insulating layer 133, the channel layer 132 on the side surface of the filling insulating layer 133, the gate insulating layer 131 on the side surface of the channel layer 132, and the pad layer 134 on an upper portion of the filling insulating layer 133.

The channel layer 132 may extend in the vertical direction (Z direction) and contact the substrate 110. In some embodiments, the channel layer 132 may be on the bottom surface as well as the side surface of the filling insulating layer 133. In other words, the channel layer 132 may extend between the filling insulating layer 133 and the gate insulating layer 131, as well as between the filling insulating layer 133 and the substrate 110. Although the channel layer 132 is illustrated as directly contacting the substrate 110 in FIG. 4A, the channel layer 132 may indirectly contact the substrate 110 via other components. The channel layer 132 may include a semiconductor material such as a Group IV semiconductor material, a Group III-V semiconductor material, and a Group II-VI semiconductor material. The Group IV semiconductor material may include, for example, Si, Ge, or Si—Ge. The Group III-V semiconductor material may include, for example, GaAs, InP, GaP, InAs, InSb, or InGaAs. The Group II-VI semiconductor material may include, for example, ZnTe, or CdS. In some embodiments, the channel layer 132 may include poly-silicon.

The gate insulating layer 131 may be between the side surface of the channel layer 132 and the side surface of the channel hole 130H. The gate insulating layer 131 may include a blocking insulating layer 131a, a charge storage layer 131b, and a tunneling insulating layer 131c, which are sequentially stacked on the side surface of the channel hole 130H. The blocking insulating layer 131a may include, for example, silicon oxide, silicon nitride, metal oxide having a dielectric constant greater than silicon oxide, or a combination thereof. The metal oxide may include hafnium oxide, aluminum oxide, zirconium oxide, tantalum oxide, or a combination thereof. The charge storage layer 131b may include, for example, silicon nitride, boron nitride, polysilicon, or a combination thereof. The tunneling insulating layer 131c may include, for example, metal oxide or silicon oxide. In some embodiments, a blocking insulating layer 131a, a charge storage layer 131b, and a tunneling insulating layer 131c may include oxide, nitride, and oxide, respectively. In some embodiments, at least a portion of the gate insulating layer 131 (for example, the blocking insulating layer 131a, the charge storage layer 131b, and the tunneling insulating layer 131c; the blocking insulating layer 131a and the charge storage layer 131b; or the blocking insulating layer 131a) may not be inside the channel hole 130H, but may be between the side surface of the channel hole 130H and each gate layer 121, and between each interlayer insulating layer 122 and each gate layer 121.

The filling insulating layer 133 may include an insulating material including, for example, silicon nitride, silicon oxide, or a combination thereof. In some embodiments, the filling insulating layer 133 may include silicon oxide. The filling insulating layer 133 may fill a space surrounded by the channel layer 132 and the pad layer 134.

The pad layer 134 may be on an upper end of the filling insulating layer 133. In some embodiments, as illustrated in FIG. 4A, the pad layer 134 may contact the side surface of the channel layer 132. In other embodiments, unlike as illustrated in FIG. 4A, the pad layer 134 may contact an upper side (e.g., a top surface) of the channel layer 132 and the side surface of the gate insulating layer 131. In other words, the channel layer 132 is illustrated in FIG. 4A as extending between the side surface of the pad layer 134 and the side surface of the gate insulating layer 131, but in some embodiments, the channel layer 132 may not extend between the side surface of the pad layer 134 and the side surface of the gate insulating layer 131. In other embodiments, the pad layer 134 may, unlike as illustrated in FIG. 4A, contact the upper side (e.g., a top surface) of the channel layer 132, an upper side (e.g., a top surface) of the gate insulating layer 131, and the side surface of the channel hole 130H. In other words, the gate insulating layer 131 is illustrated in FIG. 4A as extending between the side surface of the pad layer 134 and the side surface of the channel hole 130H, but in some embodiments, the channel layer 132 may not extend between the side surface of the pad layer 134 and the side surface of the channel hole 130H. The pad layer 134 may include a semiconductor material such as Si, Ge, and Si—Ge; a metal material such as W, Ti, Al, Cu, Au, and Ag; a metal nitride such as TiN and TaN; or a combination thereof. In some embodiments, the pad layer 134 may include poly-silicon. The pad layer 134 may facilitate the channel structure 130 to easily contact the bit line BL. In some embodiments, the filling insulating layer 133 and the pad layer 134 may be omitted. For example, the channel layer 132 may have a pillar shape extending from a lower side of the channel hole 130H to the upper side of the channel hole 130H, and a space surrounded by the gate insulating layer 131 may be filled with the channel layer 132.

Each channel structure 130 and the plurality of gate layers 121 may form one of the NAND strings NS11 through NS13, NS21 through NS23, and NS31 through NS33 illustrated in FIG. 2. For example, each channel structure 130 and one gate layer 121 may form one of the ground select transistor GST, the string select transistor SST, and the first through eighth memory cells MC1 through MC8 illustrated in FIG. 2.

Each bit line BL may extend in a first horizontal direction (X direction). Each bit line BL may connect the plurality of channel structures 130 to the peripheral circuit PC. Each bit line BL may include a conductive material including, including for example W, Cu, Ag, Au, Al, or a combination thereof. Each bit line BL is not however limited to the above described conductive materials. In some embodiments, each bit line BL may further include a barrier material including, but not limited to, Ti, Ta, TiN, TaN, or a combination thereof to prevent the conductive material from diffusing into the interlayer insulating layer 122 around each bit line BL. The channel structure 130 may be connected to the peripheral circuit PC via the bit line BL.

The common source line structure 140 may constitute some of the common source lines CSL illustrated in FIGS. 1 and 2. The common source line structure 140 may be connected to the peripheral circuit PC via a connecting member CN. The connecting member CN may include at least one line and at least one via. The common source line structure 140 may be in a common source line trench 140T penetrating the stacked structure 120 in the vertical direction (Z direction). The common source line trench 140T and the common source line structure 140 may extend in a second horizontal direction (Y direction) and the vertical direction (Z direction). The common source line structure 140 may include a side insulating layer 141 on the side surface of the common source line trench 140T, a central insulating layer 143 at the center of the common source line trench 140T, an intermediate conductive layer 142 between the side insulating layer 141 and the center insulating layer 143, and an upper conductive layer 144 at an upper portion of the common source line trench 140T. In other words, the common source line structure 140 may include the central insulating layer 143, the intermediate conductive layer 142 on the side surface of the central insulating layer 143, the side insulating layer 141 on the side surface of the intermediate conductive layer 142, and the upper conductive layer 144 on the upper portion (e.g., top surface) of the central insulating layer 143.

Each of the side insulating layer 141 and the central insulating layer 143 may include an insulating material including silicon oxide, silicon nitride, or a combination thereof. Each of the intermediate conductive layer 142 and the upper conductive layer 144 may include a metal such as for example W, Al, Au, Ag, and Cu; a metal nitride such as for example TiN, molybdenum nitride (MoN), and TaN; a semiconductor material such as for example Si, Ge, and Si—Ge; or a combination thereof.

The side insulating layer 141 may be between the side surface of the common source line trench 140T and the side surface of the intermediate conductive layer 142, and may electrically insulate the intermediate conductive layer 142 from the gate layer 121. In some embodiments, the side insulating layer 141 may extend in the vertical direction (Z direction) to contact the substrate 110.

The intermediate conductive layer 142 may extend in the vertical direction (Z direction) between the central insulating layer 143 and the side insulating layer 141 and may contact the impurity region 110D of the substrate 110. In FIG. 4A, the intermediate conductive layer 142 is illustrated as being in direct contact with the impurity region 110D of the substrate 110, but in other embodiments the intermediate conductive layer 142 may indirectly contact the impurity region 110D of the substrate 11 via other components. To facilitate contact between the intermediate conductive layer 142 and the substrate 110, the intermediate conductive layer 142 may further extend not only between the side insulating layer 141 and the central insulating layer 143, but also between the substrate 110 and the central insulating layer 143. In other words, the intermediate conductive layer 142 may be on the side surface as well as on the lower surface (e.g., bottom surface) of the central insulating layer 143. The intermediate conductive layer 142 may be electrically connected to the channel layer 132 of the channel structure 130 via, for example, the substrate 110. For example, a current may flow between the intermediate conductive layer 142 and the channel layer 132 via the substrate 110. In some embodiments, a thickness of the intermediate conductive layer 142 may be about 10 nm to about 50 nm.

The central insulating layer 143 may fill the space surrounded by the intermediate conductive layer 142 and the upper conductive layer 144. In some embodiments, as illustrated in FIG. 4A, the upper conductive layer 144 may contact the side surface of the intermediate conductive layer 142. In other embodiments, unlike as illustrated in FIG. 4A, the upper conductive layer 144 may contact the upper end (e.g., top surface) of the intermediate conductive layer 142 and the side surface of the side insulating layer 141. In other words, in FIG. 4A, the intermediate conductive layer 142 is illustrated as extending between the side surface of the upper conductive layer 144 and the side surface of the side insulating layer 141, but in some embodiments, the intermediate conductive layer 142 may not extend between the side surface of the conductive layer 144 and the side surface of the side insulating layer 141. In other embodiments, unlike as illustrated in FIG. 4A, the upper conductive layer 144 may contact the top end (e.g., top surface) of the intermediate conductive layer 142, the top end (e.g., top surface) of the side insulating layer 141, and the side surface of the common source line trench 140T. In other words, in FIG. 4A, the side insulating layer 141 extends between the side surface of the upper conductive layer 144 and the side surface of the common source line trench 140T, but in some embodiments, the side insulating layer 141 may not extend between the side surface of the upper conductive layer 144 and the side surface of the common source line trench 140T. The upper conductive layer 144 may facilitate contact to the connecting member CN of the common source line structure 140.

The memory device 100 may further include first through third interlayer insulating layers 170a, 170b, and 170c sequentially stacked on the substrate 110. The first interlayer insulating layer 170a may cover the upper surface of the substrate 110, the peripheral circuit PC, and the memory cell array MCA. The second and third interlayer insulating layers 170b and 170c may be stacked on the first interlayer insulating layer 170a. Each of the first through third interlayer insulating layers 170a, 170b, and 170c may include an insulating material including silicon oxide, silicon nitride, low-K material, or a combination thereof.

According to the inventive concepts, the common source line structure 140 may be inside the common source line trench 140T penetrating the stacked structure 120 in the vertical direction (Z direction). Accordingly, because a distance between the common source line structure 140 and the channel structure 130 may be reduced, a flow path of the current flowing between the common source line structure 140 and the channel structure 130 may be reduced. Thus, common source line noise may be reduced. In addition, according to the inventive concepts, because the space surrounded by the side insulating layer 141 may be filled with a conductive material (for example, the intermediate conductive layer 142 and the upper conductive layer 144) and an insulating material (for example, the central insulating layer 143), warpage caused by internal stress of the conductive material may be reduced with respect to the case when the entire space is filled with a conductive material.

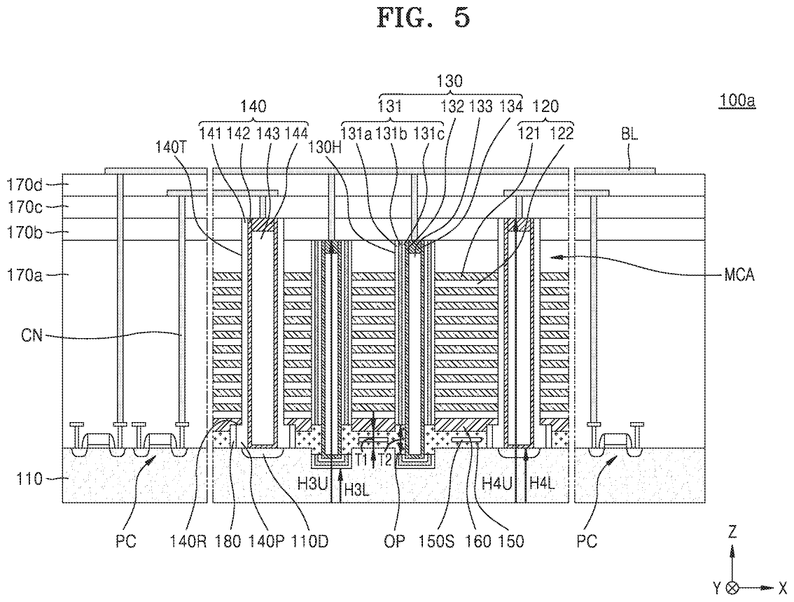

FIG. 5 illustrates a schematic cross-sectional view of a memory device 100a according to embodiments of the inventive concepts. Hereinafter, differences between the memory device 100 illustrated in FIGS. 3, 4A, and 4B and the memory device 100a illustrated in FIG. 5 are described for the sake of brevity.

Referring to FIG. 5, the memory device 100a may further include a lower conductive layer 150 between the substrate 110 and the stack structure 120. In some embodiments, the memory device 100a may further include a support layer 160 between the lower conductive layer 150 and the stack structure 120. Each of the lower conductive layer 150 and the support layer 160 may include a metal such as for example W, Al, Au, Ag, and Cu; a metal nitride such as for example TiN, molybdenum nitride (MoN), and TaN; a semiconductor material such as for example Si, Ge, and Si—Ge; or a combination thereof. In some embodiments, each of the lower conductive layer 150 and the support layer 160 may include poly-silicon.

In some embodiments, the chemical composition of the intermediate conductive layer 142 may be different from that of the lower conductive layer 150. For example, the intermediate conductive layer 142 may include a metal such as for example W, Al, Au, Ag, and Cu; a metal nitride such as for example TiN, MoN, and TaN; a semiconductor material such as for example Si, Ge, and Si—Ge; or a combination thereof. In other embodiments, conversely, the intermediate conductive layer 142 may include a semiconductor material, and the lower conductive layer 150 may include a metal or metal nitride.

In other embodiments, the chemical composition of the intermediate conductive layer 142 may be the same as that of the lower conductive layer 150. It should be understood that here the expression that the chemical composition of two components is the same means that although the chemical composition is intended to be the same, a difference in the chemical composition of the two components may be within a range of process limitations or errors that may occur. For example, each of the intermediate conductive layer 142 and the lower conductive layer 150 may include a semiconductor material such as Si, Ge, or Si—Ge. In other embodiments, each of the intermediate conductive layer 142 and the lower conductive layer 150 may include a metal such as for example W, Al, Au, Ag, or Cu. In other embodiments, each of the middle conductive layer 142 and the lower conductive layer 150 may include a metal nitride such as TiN, MoN, and TaN.

In FIG. 5, the channel hole 130H and the channel structure 130 may further penetrate not only the stacked structure 120 but also the support layer 160 and the lower conductive layer 150 and may contact the substrate 110. The common source line trench 140T and the common source line structure 140 may further penetrate not only the stacked structure 120 but also the support layer 160 and the lower conductive layer 150, and may contact the impurity region 110D of the substrate 110. The intermediate conductive layer 142 may contact the impurity region 110D of the substrate 110. The intermediate conductive layer 142 may directly and electrically contact the substrate 110. In some embodiments, the channel layer 132 may not directly contact the substrate 110. For example, the gate insulating layer 131 may further extend between the substrate 110 and the channel layer 132.

In some embodiments, a height H4U in the vertical direction (Z direction) from the lower surface of the substrate 110 to the upper end of the common source line structure 140 may be greater than a height H3U in the vertical direction (Z direction) from the lower surface of the substrate 110 to the upper end of the channel structure 130. For example, the common source line structure 140 may further penetrate a second interlayer insulating layer 170b, but the channel structure 130 may not penetrate the second interlayer insulating layer 170b. In some embodiments, a height H4L in the vertical direction (Z direction) from the lower surface of the substrate 110 to the lower end of the common source line structure 140 may be greater than a height H3L in the vertical direction (Z direction) from the lower surface of the substrate 110 to the lower end of the channel structure 130. The channel structure 130 may extend into the substrate 110.

In some embodiments, the common source line structure 140 may include a protrusion 140P in a common source line recess 140R horizontally recessed from the side surface of the common source line trench 140T into the lower conductive layer 150. For example, the protrusion 140P of the common source line structure 140 may be a portion of the side insulating layer 141. In some embodiments, the common source line recess 140R may also be horizontally further recessed from the side surface of the common source line trench 140T into the support layer 160. In other words, in some embodiments, the protrusion 140P of the common source line structure 140 may further protrude from the side surface of the common source line structure 140 into the support layer 160. In some embodiments, the memory device 100a may further include a lower insulating layer 180 between the lower conductive layer 150 and the common source line structure 140. The lower insulating layer 180 may include, for example, an oxide of a semiconductor material such as silicon oxide and germanium oxide; a metal oxide such as titanium oxide, molybdenum oxide, aluminum oxide, tungsten oxide, copper oxide, and silver oxide; a metal oxynitride such as titanium oxynitride and tantalum oxynitride; or a combination thereof.

In some embodiments, the lower conductive layer 150 may include a seam 1505. The lower conductive layer 150 may contact the channel layer 132 via a channel opening OP penetrating the gate insulating layer 131 and exposing the channel layer 132. The lower conductive layer 150 may be spaced apart from the intermediate conductive layer 142 by the side insulating layer 141. In other words, the lower conductive layer 150 may be electrically insulated from the intermediate conductive layer 142 by the side insulating layer 141. Accordingly, a current may flow through the lower conductive layer 150 and the substrate 110 between the channel layer 132 of the channel structure 130 and the intermediate conductive layer 142 of the common source line structure 140. In some embodiments, a thickness T2 of a portion inside the channel opening OP of the lower conductive layer 150 in the vertical direction (Z direction) may be greater than a thickness T1 of a portion outside the channel opening OP of the lower conductive layer 150 in the vertical direction (Z direction). In other words, the channel opening OP may be recessed upwards from the upper surface of the lower conductive layer 150 into the gate insulating layer 131 and be recessed downwards from the lower surface of the lower conductive layer 150 into the gate insulating layer 131. Accordingly, a contact area between the channel layer 132 and the lower conductive layer 150 may be increased.

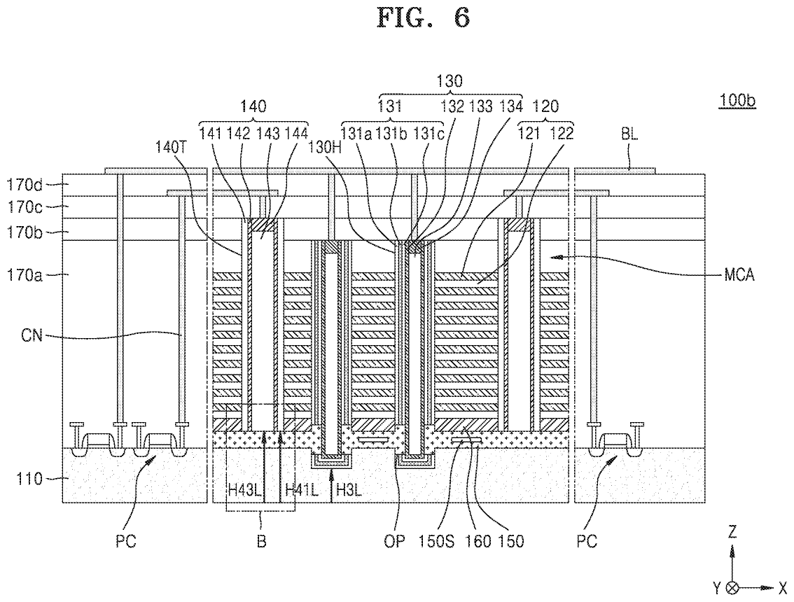

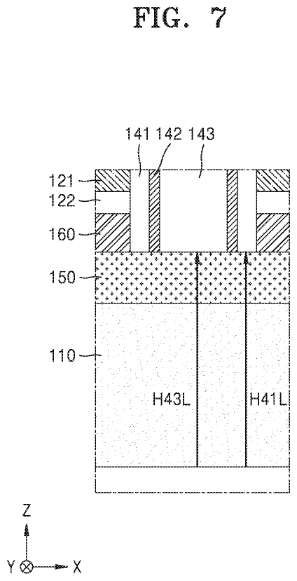

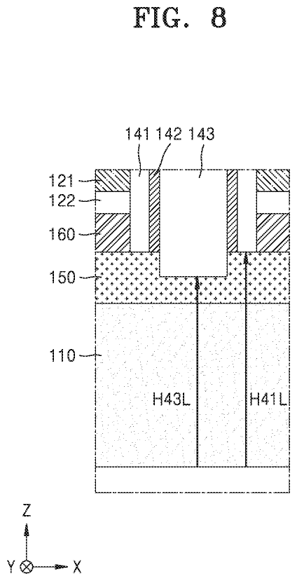

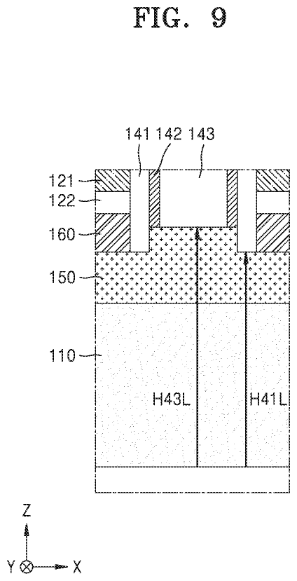

FIG. 6 illustrates a schematic cross-sectional view of a memory device 100b according to embodiments of the inventive concepts. FIG. 7 illustrates an enlarged view of a region B in FIG. 6. FIG. 8 illustrates an enlarged view of a variation example of the region B in FIG. 6. FIG. 9 illustrates an enlarged view of a variation example of the region B in FIG. 6. Hereinafter, differences between the memory device 100a illustrated in FIG. 5 and the memory device 100b illustrated in FIG. 6 are described for the sake of brevity.

Referring to FIGS. 6 and 7, the common source line structure 140 may contact the lower conductive layer 150 without directly contacting the substrate 110. In other words, the intermediate conductive layer 142 may contact the lower conductive layer 150 without directly contacting the substrate 110. Accordingly, a current may flow between the channel layer 132 of the channel structure 130 and the intermediate conductive layer 142 of the common source line structure 140 via the lower conductive layer 150.

In some embodiments, the chemical composition of the intermediate conductive layer 142 may be the same as that of the lower conductive layer 150. For example, each of the intermediate conductive layer 142 and the lower conductive layer 150 may include a semiconductor material such as Si, Ge, or Si—Ge. In other embodiments, each of the intermediate conductive layer 142 and the lower conductive layer 150 may include a metal such as for example W, Al, Au, Ag, or Cu. In other embodiments, each of the intermediate conductive layer 142 and the lower conductive layer 150 may include a metal nitride such as TiN, MoN, and TaN. In some embodiments, a boundary between the intermediate conductive layer 142 and the lower conductive layer 150 may not be visible. That is, the intermediate conductive layer 142 and the lower conductive layer 150 may be integrally formed. The intermediate conductive layer 142 may electrically contact the substrate 110 indirectly through the lower conductive layer 150.

In some embodiments, a height H41L in the vertical direction (Z direction) from the lower surface of the substrate 110 to a lower end of a side insulating layer 141 may be greater than a height H3L in the vertical direction (Z direction) from the lower surface of the substrate 110 to the lower end of the channel structure 130. For example, the side insulating layer 141 may extend to the upper surface of the lower conductive layer 150, while the channel structure 130 penetrates the lower conductive layer 150. In some embodiments, as illustrated in FIGS. 6 and 7, a height H43L in the vertical direction (Z direction) from the lower surface of the substrate 110 to the lower end of the central insulating layer 143 may be equal to a height H41L from the lower surface of the substrate 110 to the lower end of the side insulating layer 141. In other embodiments, as illustrated in FIG. 8, the height H43L in the vertical direction (Z direction) from the lower surface of the substrate 110 to the lower end of the central insulating layer 143 may be less than the height H41L from the lower surface of the substrate 110 to the lower end of the side insulating layer 141. In other embodiments, as illustrated in FIG. 9, the height H43L in the vertical direction (Z direction) from the lower surface of the substrate 110 to the lower end of the central insulating layer 143 may be greater than the height H41L from the lower surface of the substrate 110 to the lower end of the side insulating layer 141.

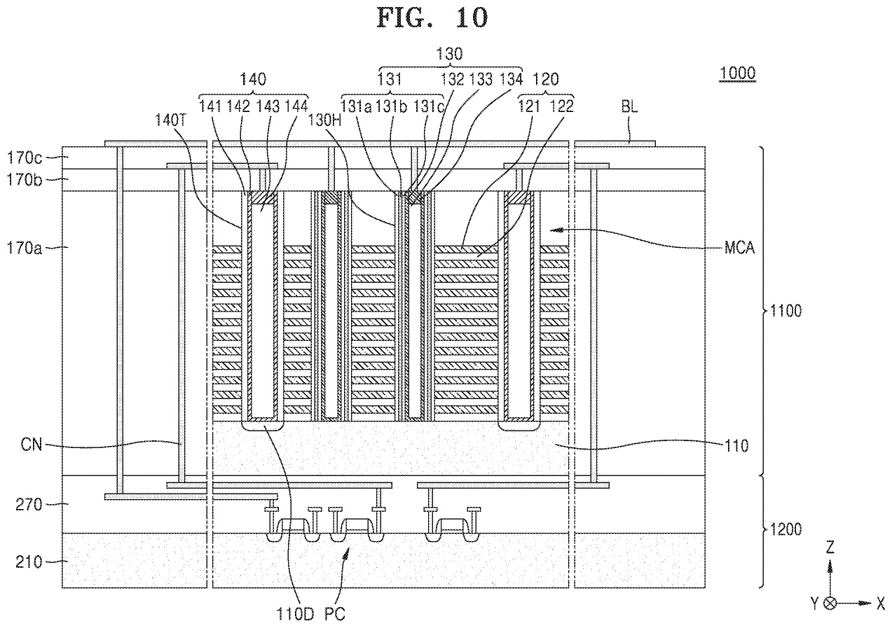

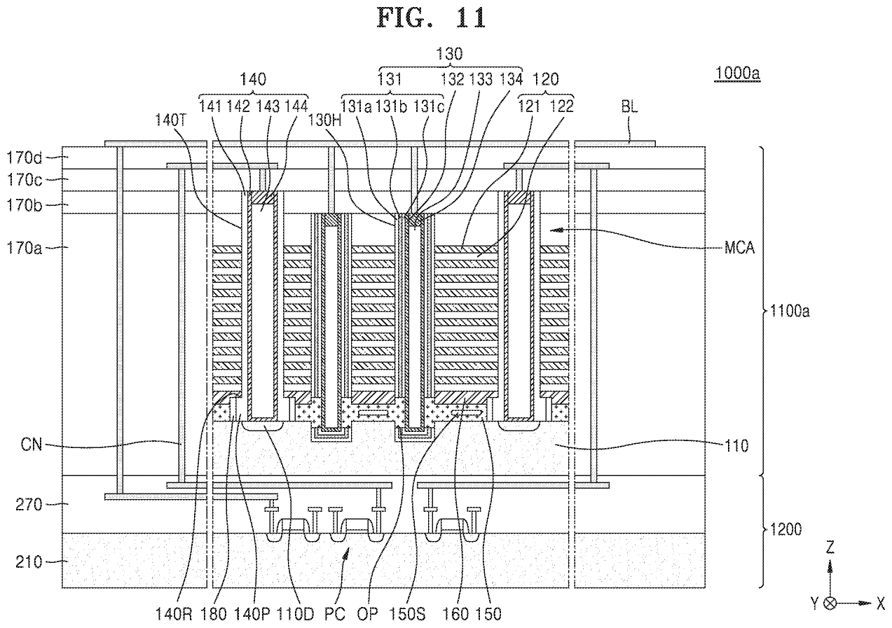

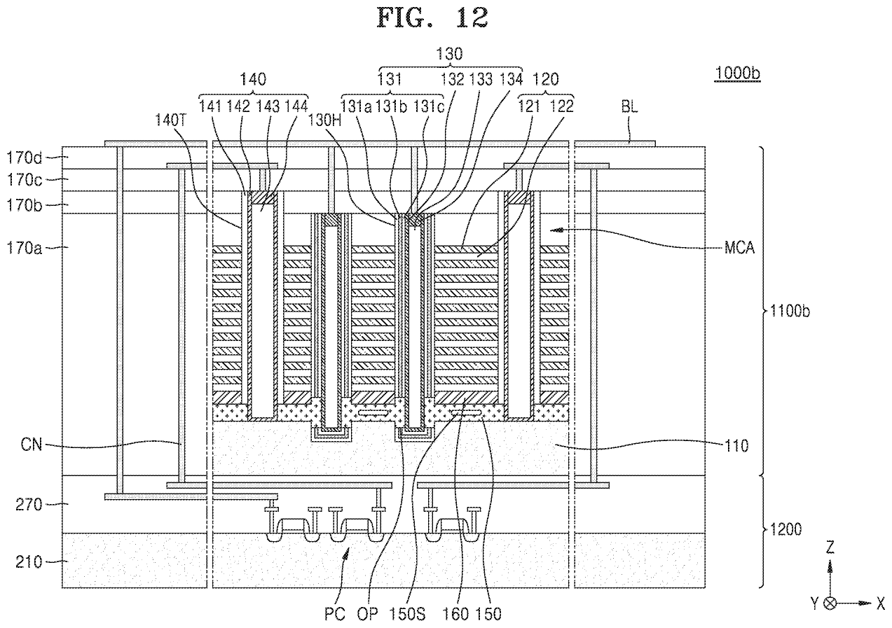

FIG. 10 illustrates a schematic cross-sectional view of a memory device 1000 according to embodiments of the inventive concepts. FIG. 11 illustrates a schematic cross-sectional view of a memory device 1000a according to embodiments of the inventive concepts. FIG. 12 illustrates a schematic cross-sectional view of a memory device 1000b according to embodiments of the inventive concepts. Hereinafter, differences between the memory devices 100, 100a, and 100b illustrated in FIGS. 4A through 6 and the memory devices 1000, 1000a, and 1000b illustrated in FIGS. 10 through 12 are described for the sake of brevity.

Referring to FIGS. 10 through 12, the memory devices 1000, 1000a, and 1000b may include a lower structure 1200 and upper structures 1100, 1100a, and 1100b on the lower structure 1200. The peripheral circuit PC may be in the lower structure 1200, and the memory cell array MCA, the bit line BL, and the common source line structure 140 may be in the upper structures 1100, 1100a, and 1100b. The peripheral circuit PC may be under the substrate 110. Accordingly, the memory devices 1000, 1000a, and 1000b illustrated in FIGS. 10 through 12 may have smaller planar areas than the memory devices 100, 100a, and 100b illustrated in FIGS. 4A through 6, respectively.

The lower structure 1200 may include a lower substrate 210, the peripheral circuit PC on the lower substrate 210, and an interlayer insulating layer 270 covering the lower substrate 210 and the peripheral circuit PC. The lower substrate 210 may include a semiconductor material such as a Group IV semiconductor material, a Group III-V semiconductor material, and a Group II-VI semiconductor material. The Group IV semiconductor material may include, for example, Si, Ge, or Si—Ge. The Group III-V semiconductor material may include, for example, GaAs, InP, GaP, InAs, InSb, or InGaAs. The Group II-VI semiconductor material may include, for example, ZnTe, or CdS. In some embodiments, the lower substrate 210 may include a bulk wafer, and the substrate 110 may include an epitaxial layer. The interlayer insulating layer 270 may include an insulating material including silicon nitride, silicon oxide, or a combination thereof.

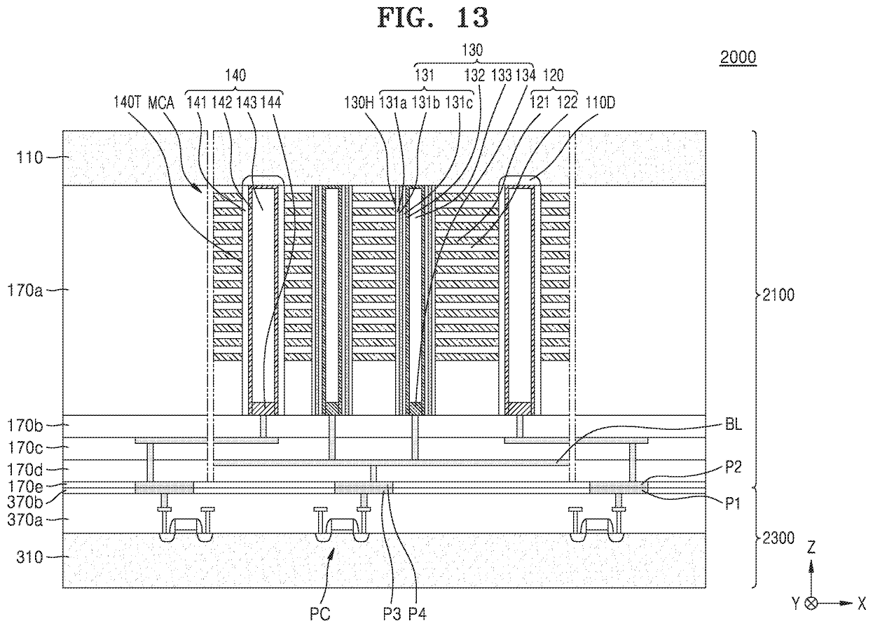

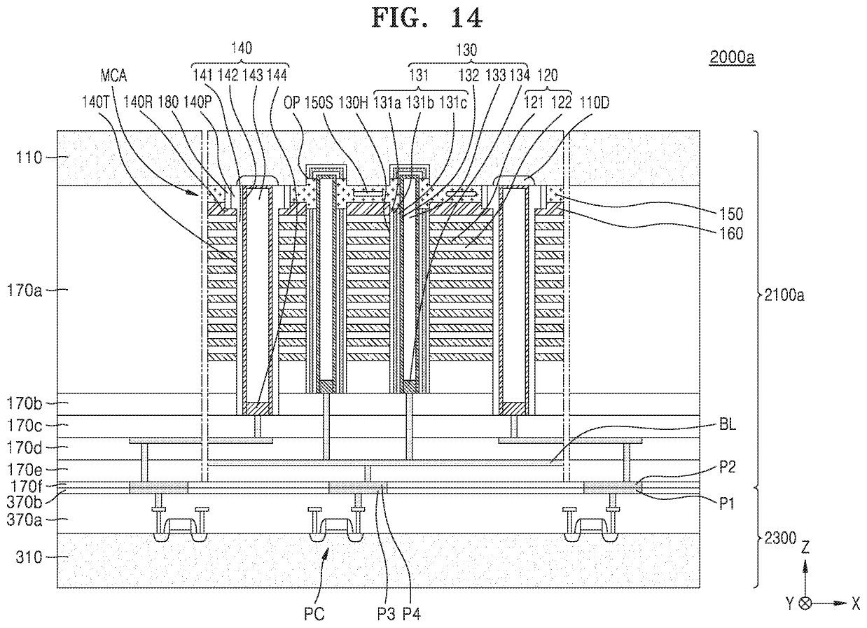

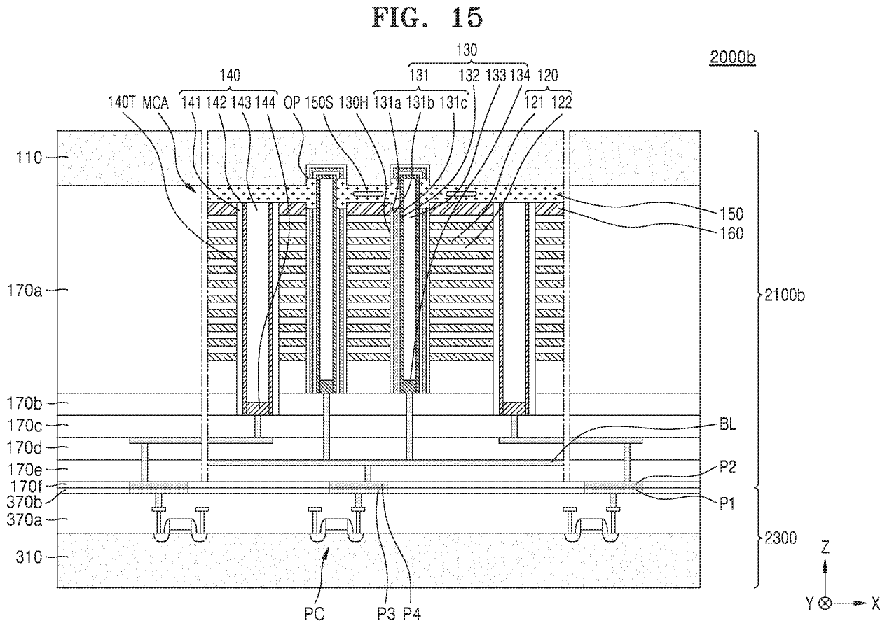

FIG. 13 illustrates a schematic cross-sectional view of a memory device 2000 according to embodiments of the inventive concepts. FIG. 14 illustrates a schematic cross-sectional view of a memory device 2000a according to embodiments of the inventive concepts. FIG. 15 illustrates a schematic cross-sectional view of a memory device 2000b according to embodiments of the inventive concepts. Hereinafter, differences between the memory devices 100, 100a, and 100b illustrated in FIGS. 4A through 6 and the memory devices 2000, 2000a, and 2000b illustrated in FIGS. 13 through 15 are described for the sake of brevity.

Referring to FIGS. 13 through 15, the memory devices 2000, 2000a, and 2000b may include a lower structure 2300 and upper structures 2100, 2100a, and 2100b on the lower structure 2300. The peripheral circuit PC may be in the lower structure 2300, and the memory cell array MCA, the bit line BL, and the common source line structure 140 may be in the upper structures 2100, 2100a, and 2100b. Because the peripheral circuit PC is formed in the lower structure 2300 under the upper structures 2100, 2100a, and 2100b, the memory devices 2000, 2000a, and 200b illustrated in FIGS. 13 through 15 may have smaller plane areas than the memory devices 100, 100a, and 100b, respectively.

The lower structure 2300 may include a lower substrate 310, the peripheral circuit PC on the lower substrate 310, a first interlayer insulating layer 370a covering the lower substrate 310 and the peripheral circuit PC, and a first pad P1 connected to the peripheral circuit PC. The lower substrate 310 may include a semiconductor material such as a Group IV semiconductor material, a Group III-V semiconductor material, and a Group II-VI semiconductor material. The Group IV semiconductor material may include, for example, Si, Ge, or Si—Ge. The Group III-V semiconductor material may include, for example, GaAs, InP, GaP, InAs, InSb, or InGaAs. The Group II-VI semiconductor material may include, for example, ZnTe, or CdS. The semiconductor substrate 310 may include a bulk wafer. The substrate 110 may include a bulk wafer or an epitaxial layer. In some embodiments, the lower structure 2300 may further include a third pad P3 connected to the peripheral circuit PC. The first pad P1 and the third pad P3 may be on the first interlayer insulating layer 370a. Each of the first pad P1 and the third pad P3 may include W, Al, Cu, Au, Ag, Ti, Ta, or a combination thereof. In some embodiments, the lower structure 2300 may further include a second interlayer insulating layer 370b on the first interlayer insulating layer 370a and that exposes the first pad P1 and the third pad P3. Each of the first interlayer insulating layer 370a and the second interlayer insulating layer 370b may include an insulating material including silicon oxide, silicon nitride, or a combination thereof.

The upper structures 2100, 2100a, and 2100b may include the substrate 110, the stacked structure 120, the channel structure 130 penetrating the stacked structure 120, the common source line structure 140 penetrating the stacked structure 120, a second pad P2 connected to the common source line structure 140, and the bit line BL connected to the channel structure 130. In some embodiments, the upper structures 2100, 2100a, and 2100b may further include a fourth pad P4 connected to the bit line BL. Each of the second pad P2 and the fourth pad P4 may include W, Al, Cu, Au, Ag, Ti, Ta, or a combination thereof. In some embodiments, as illustrated in FIG. 13, each of the second pad P2 and the fourth pad P4 may be on a fourth interlayer insulating layer 170d, and the upper structure 2100 may be on the fourth interlayer insulating layer 170d and further include a fifth interlayer insulating layer 170e exposing the second pad P2 and the fourth pad P4. In some embodiments, as illustrated in FIGS. 14 and 15, each of the second pad P2 and the fourth pad P4 may be on the fifth interlayer insulating layer 170e, and the upper structures 2100a and 2100b may be on the fifth interlayer insulating layer 170e and further include a sixth interlayer insulating layer 170f exposing the second pad P2 and the fourth pad P4. Each of the interlayer insulating layers 170a, 170b, 170c, 170d, 170e, and 170f may include an insulating material including silicon oxide, silicon nitride, or a combination thereof. In some embodiments, the upper structures 2100a and 2100b may further include the lower conductive layer 150 between the substrate 110 and the stack structure 120. In some embodiments, the upper structures 2100a and 2100b may further include the support layer 160 between the lower conductive layer 150 and the stacked structure 120.

The upper structures 2100, 2100a, and 2100b may contact the lower structure 2300 so that the second pad P2 and the fourth pad P4 of the upper structures 2100, 2100a, and 2100b contact the first pad P1 and the third pad P3 of the lower structure 2300, respectively. Accordingly, the bit lines BL and common source line structure 140 of the upper structures 2100, 2100a, and 2100b may be connected to the peripheral circuit PC of the lower structures 2300.

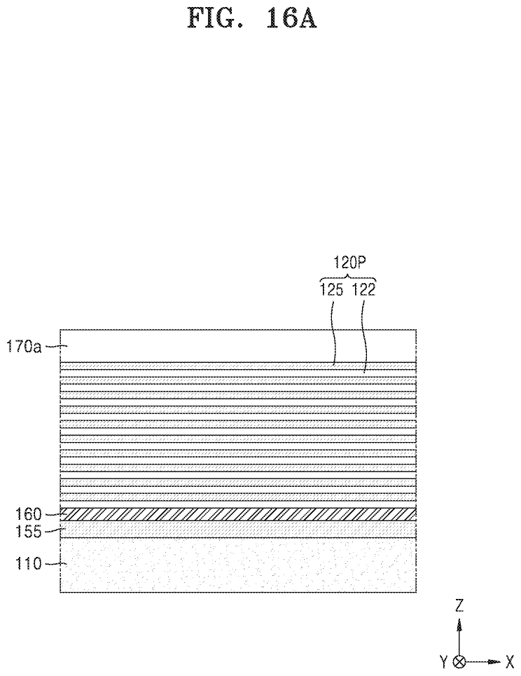

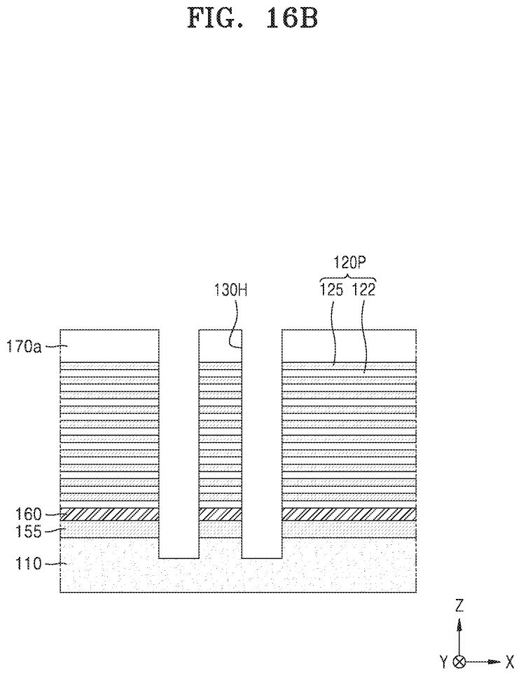

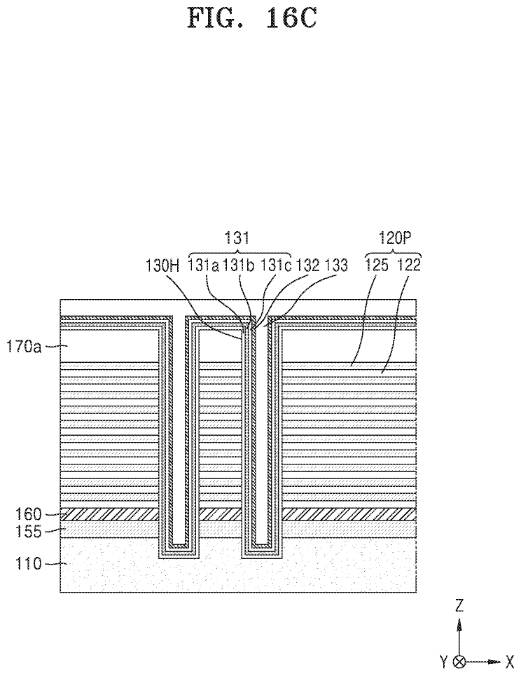

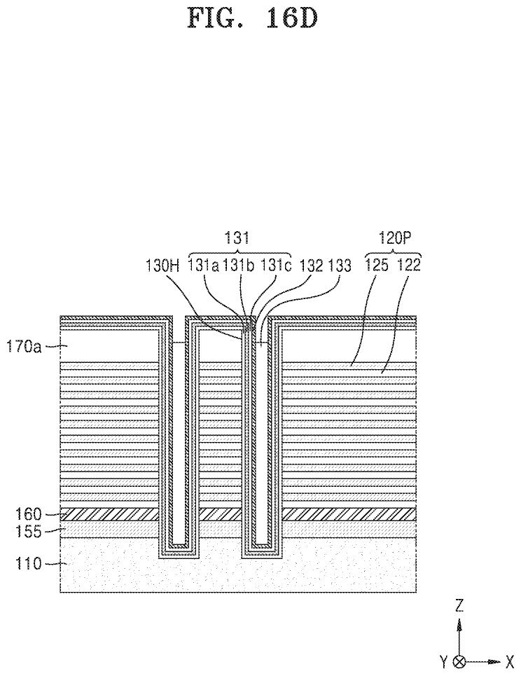

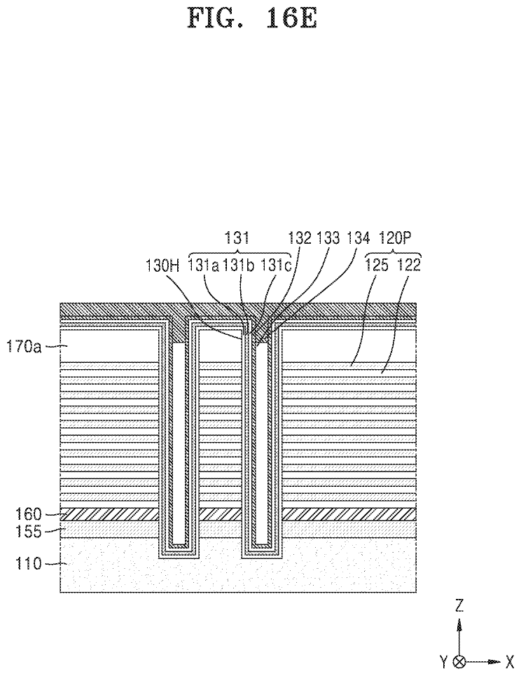

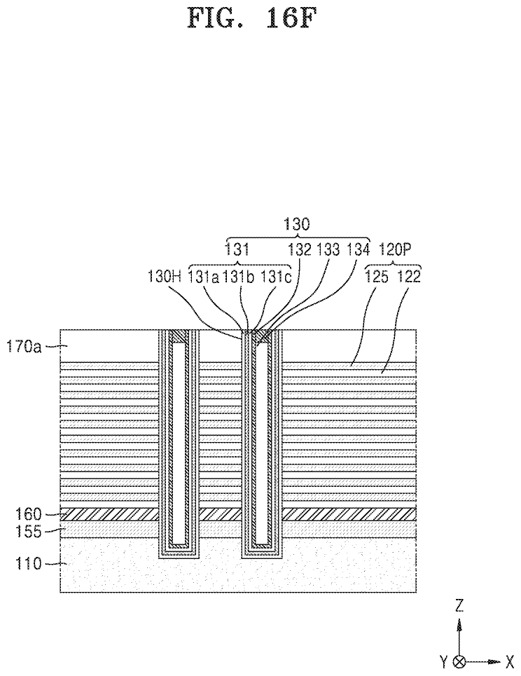

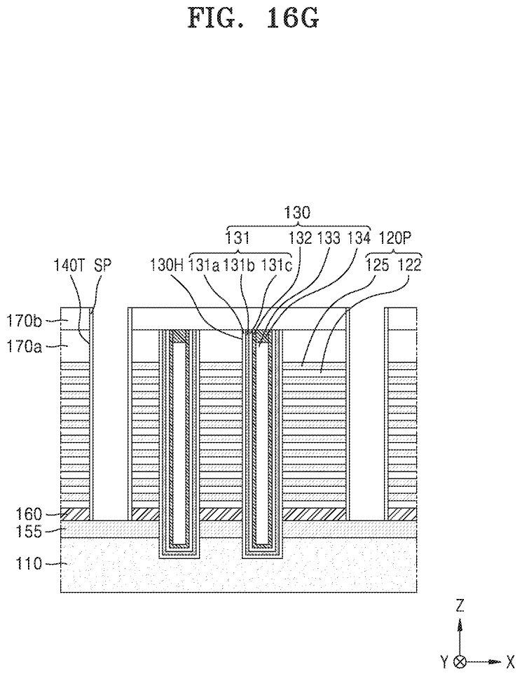

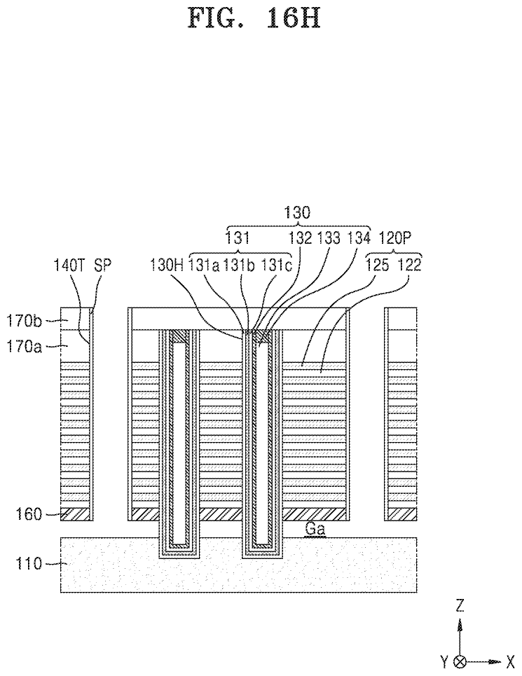

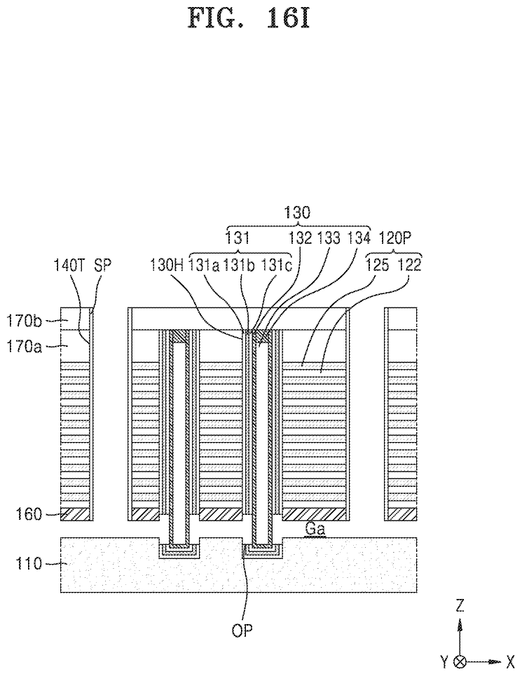

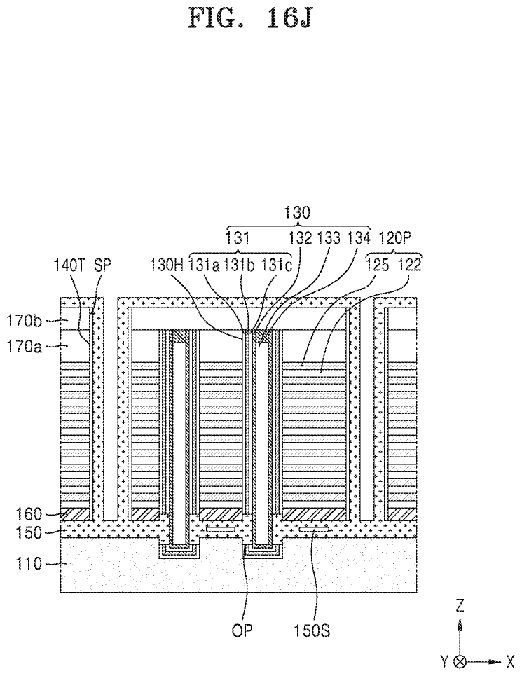

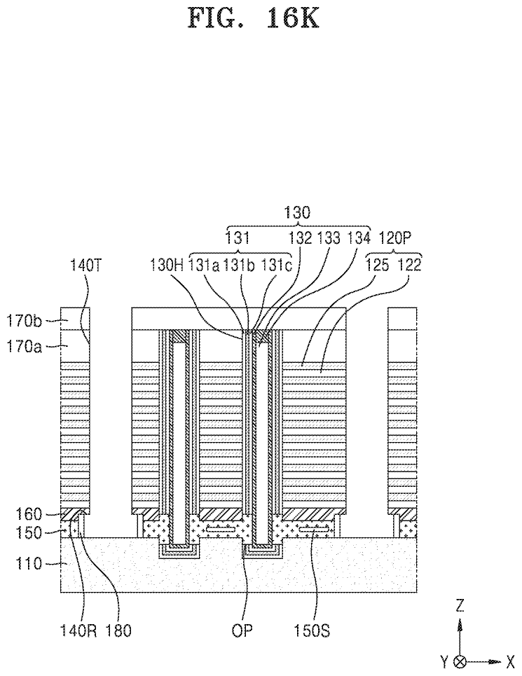

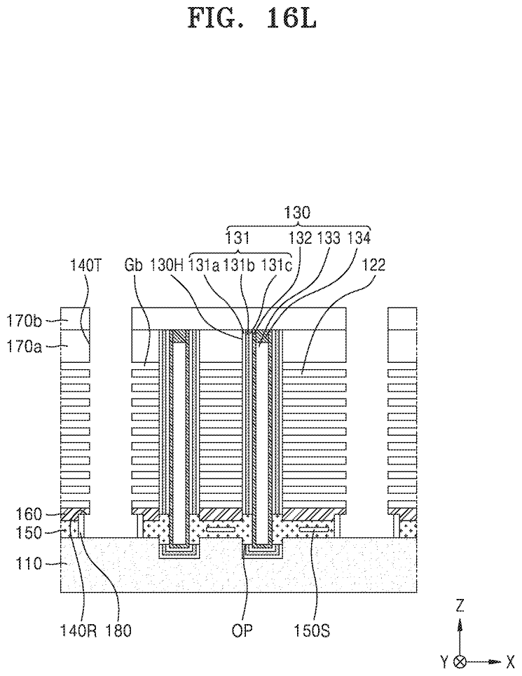

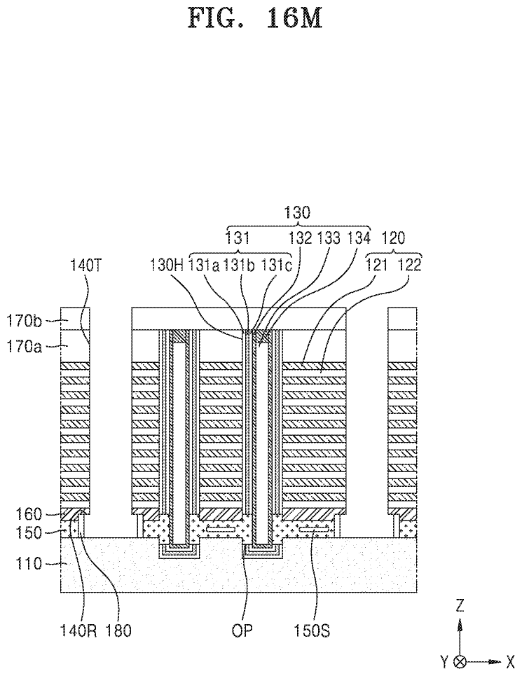

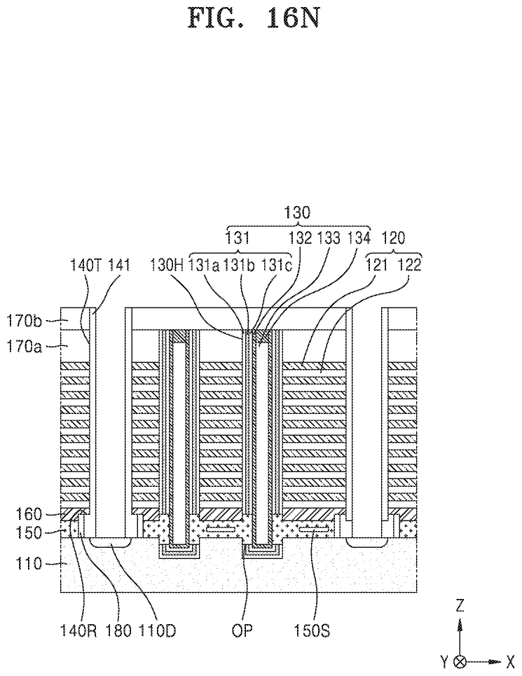

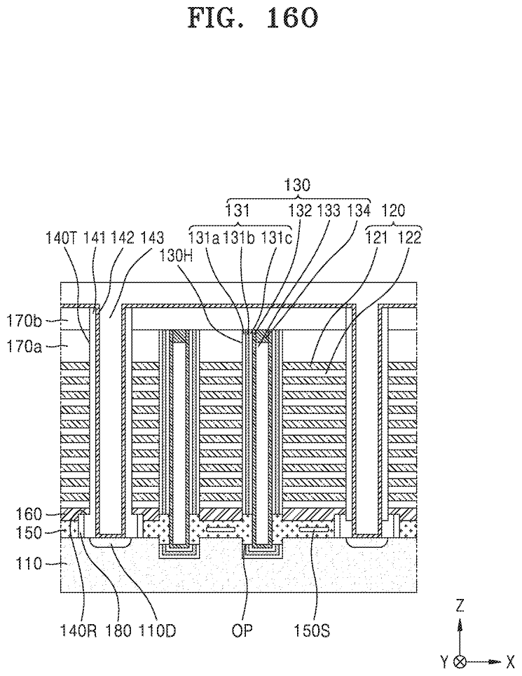

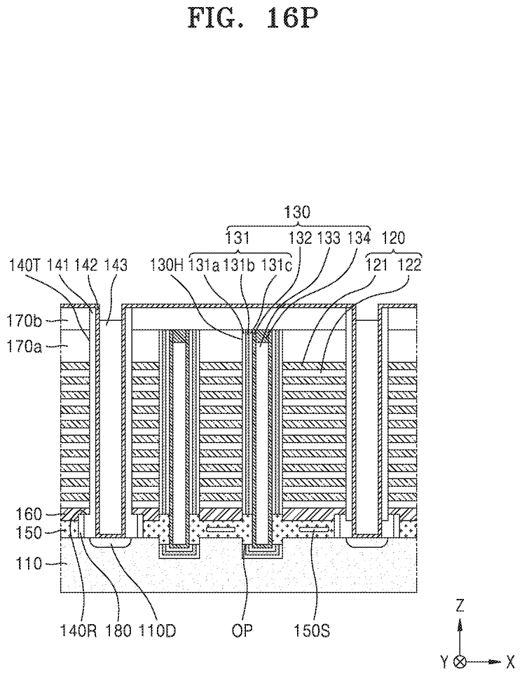

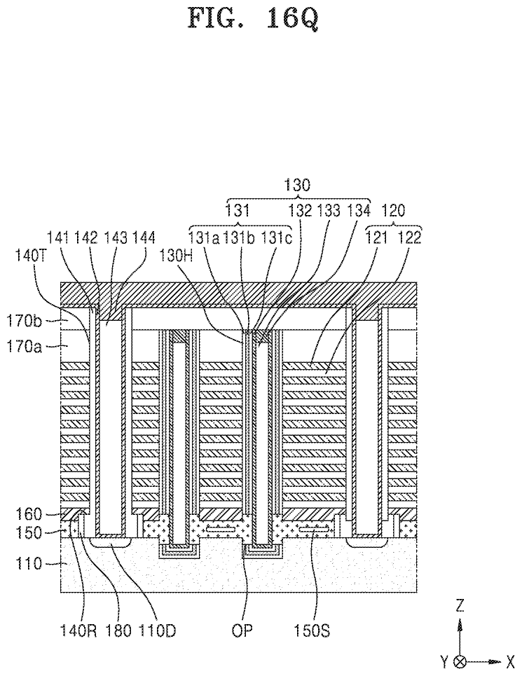

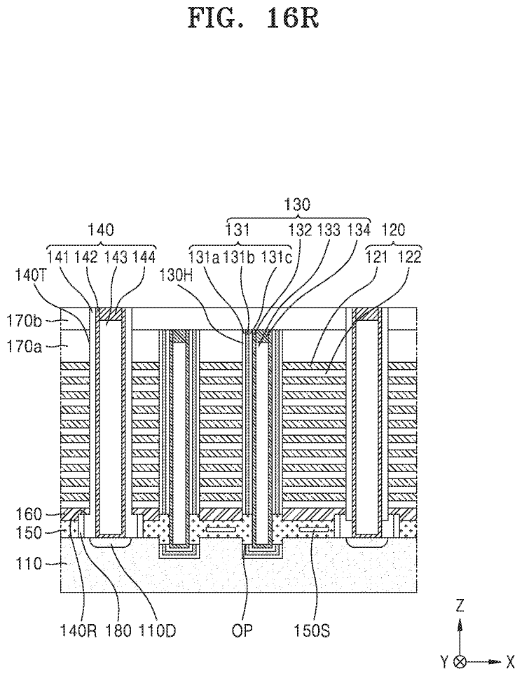

FIGS. 16A through 16R illustrate schematic cross-sectional views descriptive of a manufacturing method of a memory device, according to embodiments of the inventive concepts.

Referring to FIG. 16A, a lower sacrificial layer 155, the support layer 160, a preliminary stacked structure 120P, and the first interlayer insulating layer 170a may be formed on the substrate 110. The preliminary stacked structure 120P may include the plurality of interlayer insulating layers 122 and a plurality of sacrificial layers 125 alternately stacked on the substrate 110. The preliminary stacked structure 120P may be formed by alternately forming the plurality of interlayer insulating layers 122 and the plurality of sacrificial layers 125. The lower sacrificial layer 155 and the sacrificial layers 125 may include a material having etch selectivity with respect to the interlayer insulating layers 122, the first interlayer insulating layer 170a, and the support layer 160. In some embodiments, each of the lower sacrificial layer 155 and the sacrificial layers 125 may include silicon nitride, each of the interlayer insulating layers 122 and the first interlayer insulating layer 170a may include silicon oxide, and the support layer 160 may include silicon. In some embodiments, formation of lower sacrificial layer 155 and the support layer 160 may be omitted.

Referring to FIG. 16B, the channel hole 130H penetrating in the vertical direction (Z direction) through the first interlayer insulating layer 170a, the preliminary stacked structure 120P (that is, the interlayer insulating layers 122 and the sacrificial layers 125), the support layer 160, and the lower sacrificial layer 155A may be formed. In some embodiments, the channel hole 130H may further penetrate into the upper portion of the substrate 110.

Referring to FIG. 16C, the gate insulating layer 131, the channel layer 132, and the filling insulating layer 133 may be sequentially formed on the channel hole 130H and on the upper surface of the first interlayer insulating layer 170a. The gate insulating layer 131 may be formed by sequentially forming the blocking insulating layer 131a, the charge storage layer 131b, and the tunneling insulating layer 131c. The interlayer insulating layer 133 may be used to fill the channel hole 130H. In some embodiments, forming the filling insulating layer 133 may be omitted and the channel layer 132 may be used to fill the channel hole 130H.

Referring to FIG. 16D, the upper portion of the filling insulating layer 133 may be removed so that the upper end of the filling insulating layer 133 is lower than the upper end of the channel hole 130H (that is, an upper surface of the first interlayer insulating layer 170a) and the channel layer 132 outside the channel hole 130H is exposed. In some embodiments, the upper end of the channel layer 132 may be further removed so that the upper end of the channel layer 132 is lower than the upper end of the channel hole 130H. In some embodiments, the upper end of the gate insulating layer 131 may be further removed so that the upper end of the gate insulating layer 131 is lower than the upper end of the channel hole 130H.

Referring to FIG. 16E, the pad layer 134 may be formed on the filling insulating layer 133 and the channel layer 132 outside the channel hole 130H so that the pad layer 134 fills the upper portion of the channel hole 130H.

Referring to FIG. 16F, portions of the pad layer 134 and the channel layer 132 outside the channel hole 130H, and for example a portion on the first interlayer insulating layer 170a, may be removed. The channel structure 130 may thus be formed by the processing described with reference to FIGS. 16B through 16F.

Referring to FIG. 16G, the second interlayer insulating layer 170b may be formed on the first interlayer insulating layer 170a and on the channel structure 130. Next, a common source line trench 140T penetrating through the second interlayer insulating layer 170b, the first interlayer insulating layer 170a, the preliminary stacked structure 120P (that is, the sacrificial layers 125 and the interlayer insulating layers 122), and the support layer 160A may be formed. The common source line trench 140T may expose the lower sacrificial layer 155. Next, an etch stop layer SP may be formed on the side surface of the common source line trench 140T. For example, the etch stop layer SP may be formed on the side surface of the common source line trench 140T, the upper surface of the lower sacrificial layer 155, and the upper surface of the second interlayer insulating layer 170b, and by using anisotropic etching, portions of the etch stop layer SP on the upper surface of the lower sacrificial layer 155 and the upper surface of the second interlayer insulating layer 170b may be removed. Alternatively, by forming the etch stop layer SP by using a deposition method that does not have good step coverage characteristics, the etch stop layer SP may be formed not on the lower sacrificial layer 155, but on the upper surface of the second interlayer insulating layer 170b and the side surface of the common source line trench 140T. The etch stop layer SP may include a material having etch selectivity with respect to the lower sacrificial layer 155. For example, when the lower sacrificial layer 155 includes silicon nitride, the etch stop layer SP may include silicon or silicon oxide.

Referring to FIGS. 16G and 16H, a gap Ga may be formed between the substrate 110 and the support layer 160 by removing the lower sacrificial layer 155. The gap Ga may expose the side surface of the channel structure 130. For example, as an etchant reaches the lower sacrificial layer 155 through the common source line trench 140T, the lower sacrificial layer 155 may be etched. During the etching of the lower sacrificial layer 155, the etch stop layer SP may prevent the sacrificial layers 125 from being etched. Although not illustrated, a portion of the support layer 160 may contact the substrate 110. Thus, it may be possible to prevent the gap Ga from collapsing by supporting the preliminary stacked structure 120P while etching the lower sacrificial layer 155.

Referring to FIG. 16I, a channel opening OP may be formed by removing a portion of the gate insulating layer 131 exposed to the gap Ga. The channel opening OP may expose the channel layer 132. In some embodiments, the channel opening OP may be recessed downward from a lower surface of the gap Ga into the gate insulating layer 131 and also recessed upward from an upper surface of the gap Ga into the gate insulating layer 131.

Referring to FIGS. 16I and 16J, the lower conductive layer 150 may be formed inside the gap Ga and the channel opening OP. When the gap Ga is filled with the lower conductive layer 150, the seam 1505 may be formed. When the gap Ga is filled with the lower conductive layer 150, the lower conductive layer 150 may be further formed on the second interlayer insulating layer 170b and the etch stop layer SP.

Referring to FIGS. 16J and 16K, portions of the lower conductive layer 150 on the second interlayer insulating layer 170b and on the etch stop layer SP, and a portion of the lower conductive layer 150 exposed at the bottom of the common source line trench 140T may be removed. When portions of the lower conductive layer 150 exposed at the bottom of the common source line trench 140T are removed, the common source line recess 140R recessed from the side surface of the common source line trench 140T into the lower conductive layer 150 may be formed. The lower insulating layer 180 may be further formed by oxidizing the lower conductive layer 150. In some embodiments, the common source line recess 140R may be formed to also be recessed into the support layer 160, and the support layer 160 may be further oxidized when the lower conductive layer 150 is oxidized. Next, the etch stop layer SP may be removed.

Referring to FIGS. 16K and 16L, the gap Gb between the uppermost interlayer insulating layer 122 of the stacked structure 120 and the interlayer insulating layer 170a may be formed by removing the sacrificial layers 125. Gaps may also be formed between the remaining interlayer insulating layers 122 by removing the sacrificial layers 125. The etchant may be transferred to the sacrificial layers 125 through the common source line trench 140T to etch the sacrificial layers 125.

Referring to FIGS. 16L and 16M, the gate layers 121 may be formed in the gap Gb and in the gaps between the remaining interlayer insulating layers 122 of the stacked structure 120. As described with reference to FIGS. 16K through 16M, the stacked structure 120 including the gate layers 121 and the interlayer insulating layers 122 may thus be formed by replacing the sacrificial layers 125 with the gate layers 121.

Referring to FIG. 16N, the side insulating layer 141 may be formed on the side surface of the common source line trench 140T. For example, the side insulating layer 141 may be formed on the side surface of the common source line trench 140T, the upper surface of the substrate 110, and the upper surface of the second interlayer insulating layer 170b. Thereafter, portions of the side insulating layer 141 on the upper surface of substrate 110 and on the upper surface of the second interlayer insulating layer 170b may be removed by an anisotropic etching. In addition, the impurity region 110D may be formed by, for example, implanting impurities into a portion of the substrate 110 exposed by the common source line trench 140T.

Referring to FIG. 16O, the intermediate conductive layer 142 may be formed on the side insulating layer 141 and the impurity region 110D of the substrate 110, and on the upper surface of the second interlayer insulating layer 170b. Next, the central insulating layer 143 filling the common source line trench 140T may be formed on the intermediate conductive layer 142.

Referring to FIG. 16P, the upper portion of the central insulating layer 143 may be removed so that the upper end of the central insulating layer 143 is lower than the upper end of the common source line trench 140T (that is, the upper surface of the second interlayer insulating layer 170b). The intermediate conductive layer 142 on the upper surface of the second interlayer insulating layer 170b may be exposed. In some embodiments, the upper portion of the intermediate conductive layer 142 may be further removed so that the upper end of the intermediate conductive layer 142 is lower than the upper end of the common source line trench 140T. In some embodiments, the upper portion of the side insulating layer 141 may be further removed so that the upper end of the side insulating layer 141 is lower than the upper end of the common source line trench 140T.

Referring to FIG. 16Q, the upper conductive layer 144 may be formed on the central insulating layer 143 and on the intermediate conductive layer 142.

Referring to FIGS. 16Q and 16R, portions of the intermediate conductive layer 142 and the upper conductive layer 144 outside the common source line trench 140T (that is, on the upper surface of the second interlayer insulating layer 170b) may be removed. The common source line structure 140 may thus be formed as described with reference to FIGS. 16M through 16R.

Referring to FIG. 5, the peripheral circuit PC may be further formed on the substrate 110 before the first interlayer insulating layer 170a is formed. In addition, after the common source line structure 140 is formed, the third interlayer insulating layer 170c may be further formed on the second interlayer insulating layer 170b, and thereafter, the connecting member CN may be further formed. In addition, after the third interlayer insulating layer 170c is formed, the fourth interlayer insulating layer 170d may be further formed on the third interlayer insulating layer 170c, and thereafter the bit line BL may be further formed.

In the alternative, referring to FIG. 11, the lower structure 1200 may be formed by forming the peripheral circuit PC and the interlayer insulating layer 270 on the lower substrate 210. Next, the substrate 110 may be formed on the lower structure 1200. Next, except for the process of forming the peripheral circuit PC on the substrate 110, the upper structure 1100a may be formed on the lower structure 1200 according to the processing described with reference to FIGS. 16A through 16R and FIG. 5.

As a still further alternative, referring to FIG. 14, the lower structure 2300 may be formed by forming the peripheral circuit PC and the first interlayer insulating layer 370a on the lower substrate 310, and forming the second interlayer insulating layer 370b, the first pad P1, and the third pad P3 on the first interlayer insulating layer 370a. Except for the process of forming the peripheral circuit PC on the substrate 110, the processes described with reference to FIGS. 16A through 16R and FIG. 5 may be performed. Next, the fifth interlayer insulating layer 170e may be further formed on the fourth interlayer insulating layer 170d. Next, the sixth interlayer insulating layer 170f, the second pad P2, and the fourth pad P4 may be further formed on the fifth interlayer insulating layer 170e. Thus, the upper structure 2100a may be formed. Next, the upper structure 2100a may be bonded to the lower structure 2300 so that the first pad P1 contacts the second pad P2, and the third pad P3 contacts the fourth pad P4.

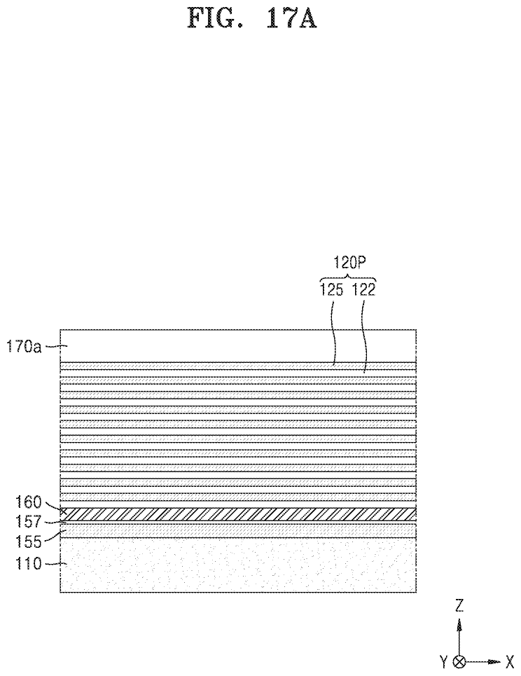

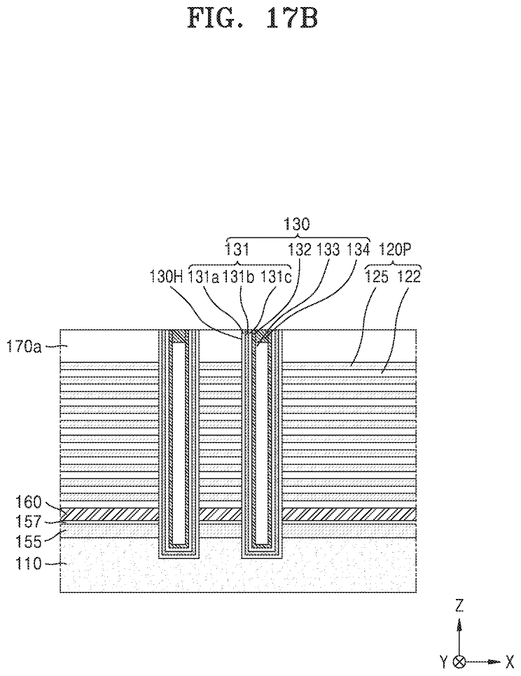

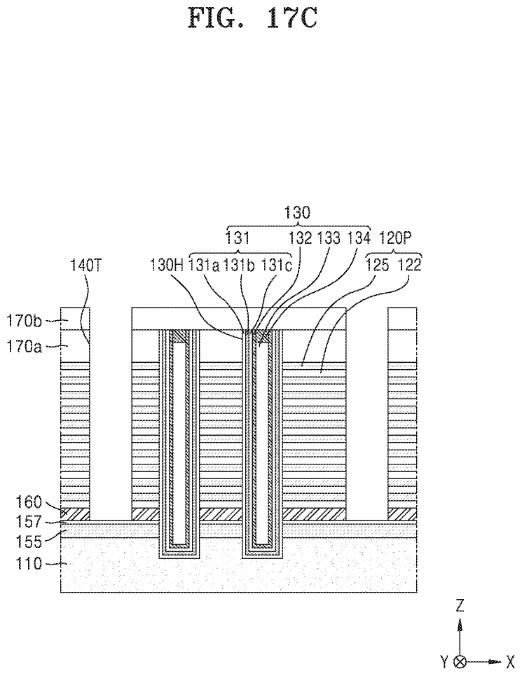

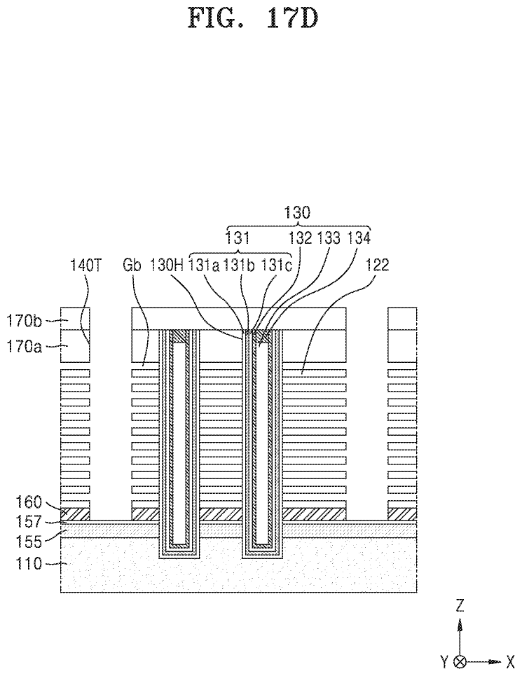

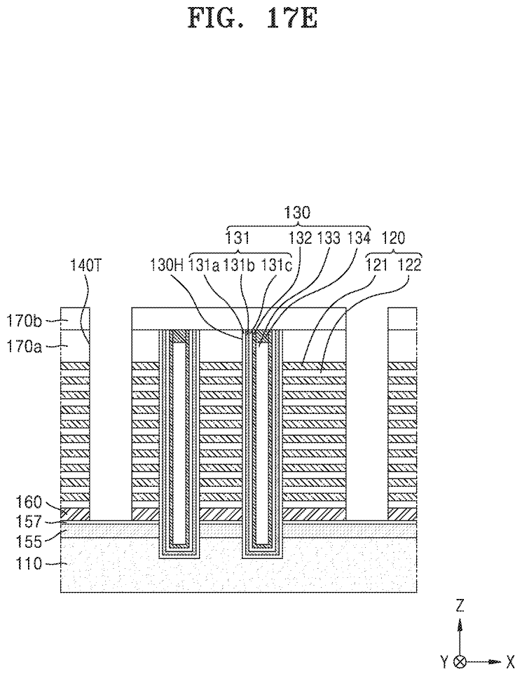

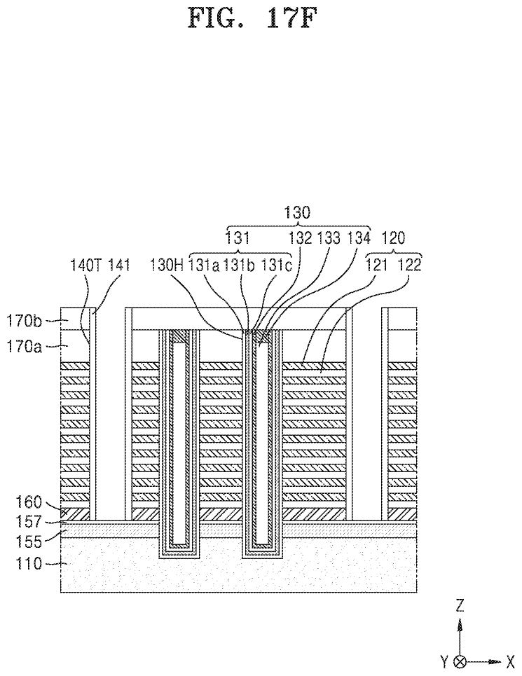

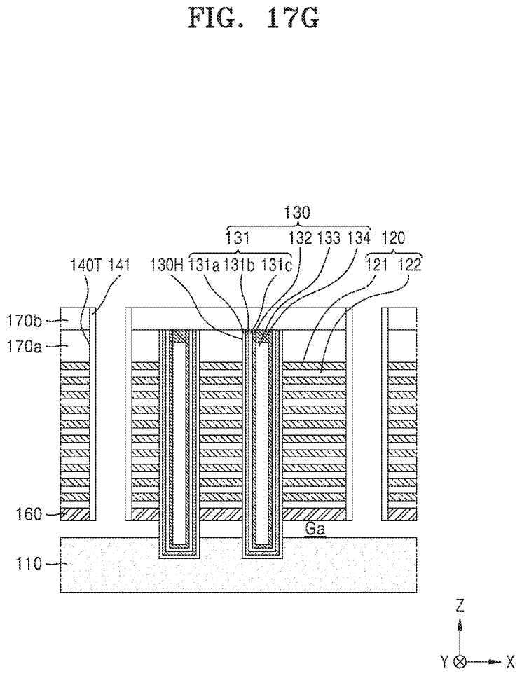

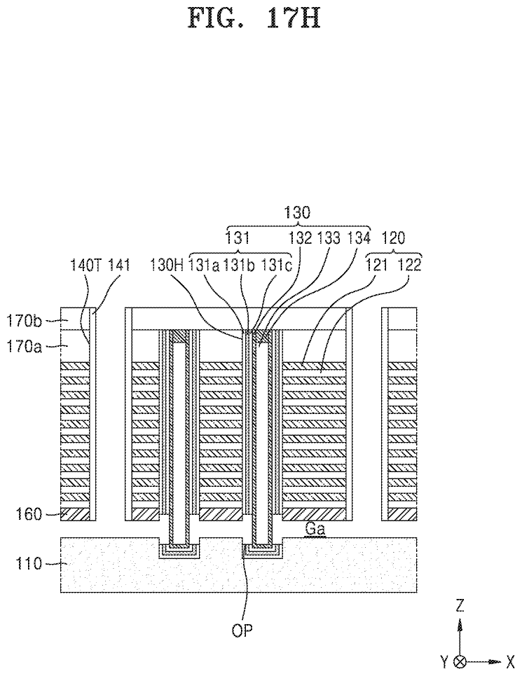

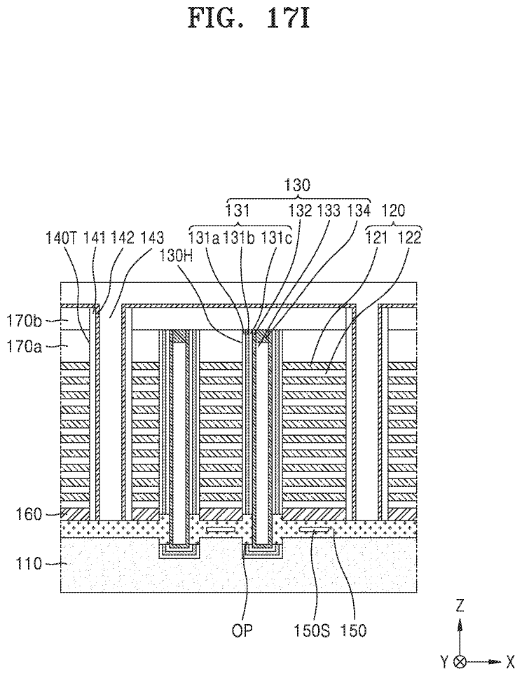

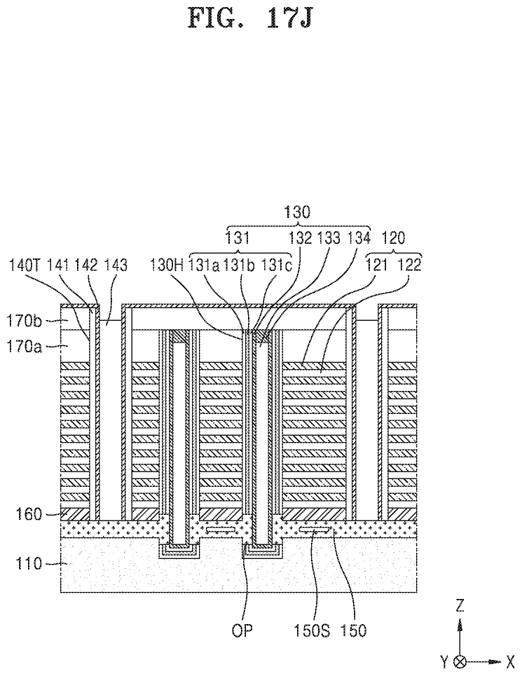

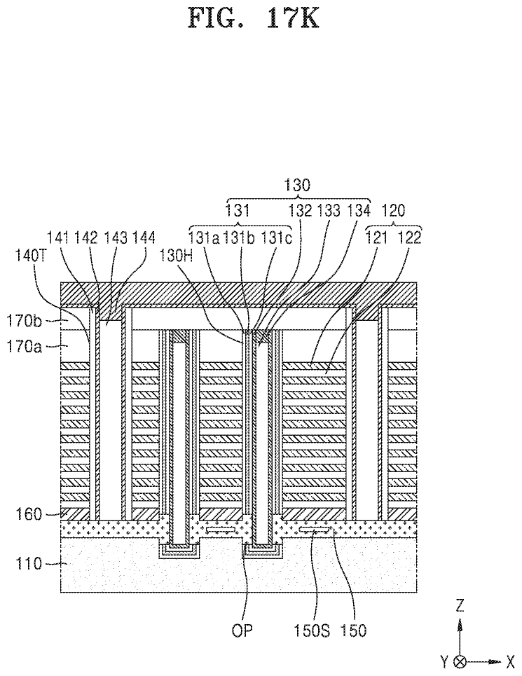

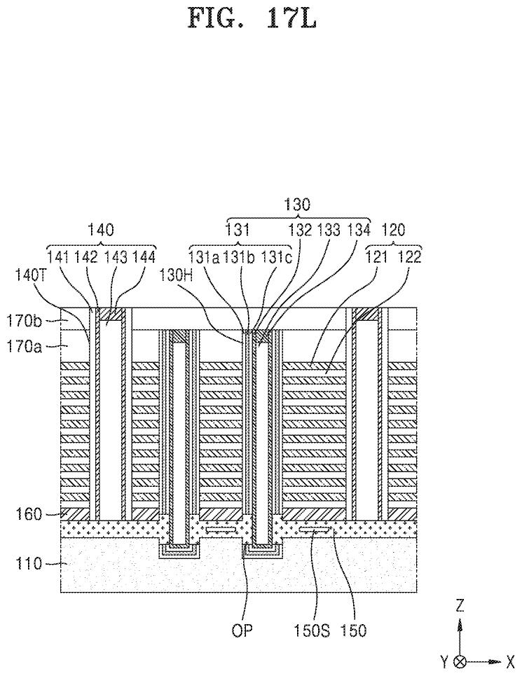

FIGS. 17A through 17I illustrate schematic cross-sectional views descriptive of a manufacturing method of a memory device, according to embodiments of the inventive concepts.

Referring to FIG. 17A, a lower sacrificial layer 155, a lower etch stop layer 157, a support layer 160, a preliminary stacked structure 120P, and a first interlayer insulating layer 170a may be sequentially formed on the substrate 110. The lower etch stop layer 157 may include a material having etch selectivity with respect to the lower sacrificial layer 155. For example, the lower sacrificial layer 155 may include silicon nitride and the lower etch stop layer 157 may include silicon oxide.

Referring to FIG. 17B, the channel structure 130 may be formed in the same manner as described with reference to FIGS. 16B through 16F. The channel hole 130H and the channel structure 130 may also penetrate the lower etch stop layer 157.

Referring to FIG. 17C, the second interlayer insulating layer 170b may be formed on the first interlayer insulating layer 170a and channel structure 130. Next, a common source line trench 140T penetrating through the second interlayer insulating layer 170b, the first interlayer insulating layer 170a, the preliminary stacked structure 120P (that is, the sacrificial layers 125 and the interlayer insulating layers 122), and the support layer 160A may be formed. The common source line trench 140T may expose the lower etch stop layer 157 and the sacrificial layers 125.

Referring to FIGS. 17C and 17D, the gap Gb may be formed between an uppermost interlayer insulating layer 122 of the stacked structure 120 and the first interlayer insulating layer 170a, and gaps may be formed between the remaining interlayer insulating layers 122 of the stacked structure 120, by removing the sacrificial layers 125. The etchant may be transferred to the sacrificial layers 125 through the common source line trench 140T and the sacrificial layers 125 may be etched. While the sacrificial layers 125 are etched, the lower etch stop layer 157 may prevent the etchant from reaching the lower sacrificial layer 155.

Referring to FIGS. 17D and 17E, the gap Gb and the gaps between the remaining interlayer insulating layers 122 of the stacked structure 120 may be filled with the gate layers 121. As described with reference to FIGS. 17C through 17E, the stacked structure 120 including the gate layers 121 and the interlayer insulating layers 122 may be formed by replacing the sacrificial layers 125 with the gate layers 121.

Referring to FIG. 17F, the side insulating layer 141 may be formed on the side surface of the common source line trench 140T. For example, the side insulating layer 141 may be formed on the side surface of the common source line trench 140T, the upper surface of the second interlayer insulating layer 170b, and the upper surface of the lower etch stop layer 157, and thereafter, portions of the side insulating layer 141 on the upper surface of the second interlayer insulating layer 170b and the upper surface of the lower etch stop layer 157 may be removed by using anisotropic etching, and a portion of the side insulating layer 141 on the side surface of the common source line trench 140T may remain.

Referring to FIG. 17G, the gap Ga may be formed between the substrate 110 and the support layer 160 by removing the lower etch stop layer 157 and the lower sacrificial layer 155. The gap Ga may expose the side surface of the channel structure 130.

Referring to FIG. 17H, the channel opening OP may be formed by removing a portion of the gate insulating layer 131 exposed to the gap Ga. The channel opening OP may expose the channel layer 132.

Referring to FIGS. 17H and 17I, the lower conductive layer 150 may be formed in the gap Ga and the channel opening OP. While the lower conductive layer 150 is formed, the intermediate conductive layer 142 may be formed on the side surface of the side insulating layer 141. The intermediate conductive layer 142 may contact the lower conductive layer 150. In some embodiments, the lower conductive layer 150 and the intermediate conductive layer 142 may be integrally and simultaneously formed, and the lower conductive layer 150 and the intermediate conductive layer 142 may have the same chemical composition. When the gap Ga is filled with the lower conductive layer 150, the seam 1505 may be formed. When the intermediate conductive layer 142 is formed on the side surface of the side insulating layer 141, the intermediate conductive layer 142 may be further formed on the upper surface of the second interlayer insulating layer 170b. Next, the central insulating layer 143 may be formed on the intermediate conductive layer 142 and the lower conductive layer 150 so that the central insulating layer 143 fills the common source line trench 140T.

Referring to FIG. 17J, the upper portion of the central insulating layer 143 may be removed so that the upper end of the central insulating layer 143 is lower than the upper end of the common source line trench 140T (that is, the upper surface of the second interlayer insulating layer 170b). The central insulating layer 143 is also removed from the upper surface of the intermediate conductive layer 142 outside the common source line trench 140T. In some embodiments, the upper portion of the intermediate conductive layer 142 may be further removed so that the upper end of the intermediate conductive layer 142 is lower than the upper end of the common source line trench 140T. In some embodiments, the upper portion of the side insulating layer 141 may be further removed so that the upper end of the side insulating layer 141 is lower than the upper end of the common source line trench 140T.

Referring to FIG. 17K, the upper conductive layer 144 may be formed on the central insulating layer 143 and on the intermediate conductive layer 142 outside the common source line trench 140T.

Referring to FIGS. 17K and 17L, portions of the intermediate conductive layer 142 and the upper conductive layer 144 outside the common source line trench 140T (that is, on the upper surface of the second interlayer insulating layer 170b) may be removed. The common source line structure 140 may thus be formed by the processes described with reference to FIGS. 17E through 17L.

Referring to FIG. 6, the peripheral circuit PC may be further formed on the substrate 110 before the first interlayer insulating layer 170a is formed. In addition, after the common source line structure 140 is formed, the third interlayer insulating layer 170c may be further formed on the second interlayer insulating layer 170b, and thereafter, the connecting member CN may be further formed. In addition, after the third interlayer insulating layer 170c is formed, the fourth interlayer insulating layer 170d may be further formed on the third interlayer insulating layer 170c, and thereafter the bit line BL may be further formed.

In the alternative, referring to FIG. 12, the lower structure 1200 may be formed by forming the peripheral circuit PC and the interlayer insulating layer 270 on the lower substrate 210. Next, the substrate 110 may be formed on the lower structure 1200. Next, except for a process of forming the peripheral circuit PC on the substrate 110, the upper structure 1100b may be formed on the lower structure 1200 according to the processes described with reference to FIGS. 17A through 17I and FIG. 6.

As a further alternative, referring to FIG. 15, the lower structure 2300 may be formed by forming the peripheral circuit PC and the first interlayer insulating layer 370a on the lower substrate 310, and forming the second interlayer insulating layer 370b, the first pad P1, and the third pad P3 on the first interlayer insulating layer 370a. Except for a process of forming the peripheral circuit PC on the substrate 110, the operations described with reference to FIGS. 17A through 17I and FIG. 6 may be performed. Next, the fifth interlayer insulating layer 170e may be further formed on the fourth interlayer insulating layer 170d. Next, the sixth interlayer insulating layer 170f, the second pad P2, and the fourth pad P4 may be further formed on the fifth interlayer insulating layer 170e. Thus, the upper structure 2100b may be formed. Next, the upper structure 2100b may be bonded to the lower structure 2300 so that the first pad P1 contacts the second pad P2, and the third pad P3 contacts the fourth pad P4.

While the inventive concepts have been particularly shown and described with reference to embodiments thereof, it should be understood that various changes in form and detail may be made therein without departing from the spirit and scope of the following claims.

What is claimed is:

1. A memory device comprising:
a substrate;
a lower conductive layer on the substrate;
a stacked structure on the lower conductive layer, the stacked structure comprising gate layers and interlayer insulating layers alternately stacked on the lower conductive layer;
a channel structure in a channel hole that penetrates the stacked structure in a vertical direction; and
a common source line structure in a common source line trench that penetrates the lower conductive layer and the stacked structure in the vertical direction,
wherein the common source line structure comprises a side insulating layer on a side surface of the common source line trench, a central insulating layer at a central portion of the common source line trench, an intermediate conductive layer between the side insulating layer and the central insulating layer, and an upper conductive layer at an upper portion of the common source line trench.

2. The memory device of claim 1, wherein the intermediate conductive layer further extends between the substrate and the central insulating layer.

3. The memory device of claim 1, wherein the channel hole and the channel structure further penetrate the lower conductive layer.

4. The memory device of claim 1, wherein a height in the vertical direction from a lower surface of the substrate to an upper end of the common source line structure is greater than a height in the vertical direction from the lower surface of the substrate to an upper end of the channel structure.

5. The memory device of claim 1, wherein a height in the vertical direction from a lower surface of the substrate to a lower end of the common source line structure is greater than a height in the vertical direction from the lower surface of the substrate to a lower end of the channel structure.

6. The memory device of claim 1, wherein the common source line structure comprises a protrusion that extends into a common source line recess that is horizontally recessed from the side surface of the common source line trench into the lower conductive layer.

7. The memory device of claim 6, further comprising a lower insulating layer between the lower conductive layer and the protrusion of the common source line structure.

8. The memory device of claim 1, wherein a chemical composition of the intermediate conductive layer is different from a chemical composition of the lower conductive layer.

9. The memory device of claim 1, further comprising a support layer between the lower conductive layer and the stacked structure.

10. The memory device of claim 1, further comprising a lower structure under the substrate,
wherein the lower structure comprises a lower substrate and a peripheral circuit on the lower substrate, the peripheral circuit connected to the common source line structure.

11. A memory device comprising:
a substrate;
a lower conductive layer on the substrate;
a stacked structure on the lower conductive layer, the stacked structure comprising gate layers and intermediate insulating layers alternately stacked on the lower conductive layer;
a channel structure inside a channel hole that penetrates the lower conductive layer and the stacked structure in a vertical direction; and
a common source line structure in a common source line trench that penetrates the stacked structure in the vertical direction,
wherein the common source line structure comprises a side insulating layer on a side surface of the common source line trench, a central insulating layer at a center portion of the common source line trench, an intermediate conductive layer between the side insulating layer and the central insulating layer, and an upper conductive layer at an upper portion of the common source line trench,
wherein the intermediate conductive layer contacts the lower conductive layer.

12. The memory device of claim 11, wherein a chemical composition of the intermediate conductive layer is identical to a chemical composition of the lower conductive layer.

13. The memory device of claim 11, wherein a height in the vertical direction from a lower surface of the substrate to a lower end of the central insulating layer is less than a height in the vertical direction from the lower surface of the substrate to a lower end of the side insulating layer.

14. The memory device of claim 11, wherein a height in the vertical direction from a lower surface of the substrate to a lower end of the central insulating layer is greater than a height in the vertical direction from the lower surface of the substrate to a lower end of the side insulating layer.

15. The memory device of claim 11, wherein the channel structure comprises a gate insulating layer on a side surface of the channel hole, a filling insulating layer at an central portion of the channel hole, a channel layer between the gate insulating layer and the filling insulating layer, and a pad layer at an upper portion of the channel hole,
wherein the lower conductive layer penetrates the gate insulating layer and contacts the channel layer via a channel opening configured to expose the channel layer.

16. The memory device of claim 15, wherein a thickness in the vertical direction of a portion of the lower conductive layer inside the channel opening is greater than a thickness of a portion of the lower conductive layer outside the channel opening.

17. The memory device of claim 11, further comprising a lower structure under the substrate,
wherein the lower structure comprises a lower substrate and a peripheral circuit on the lower substrate, the peripheral circuit connected to the common source line structure.

18. A memory device comprising:
a lower structure; and
an upper structure on the lower structure,
wherein the lower structure comprises a substrate, a peripheral circuit on the substrate, and a first pad connected to the peripheral circuit,
wherein the upper structure comprises a stacked structure comprising gate layers and intermediate insulating layers alternately stacked in a vertical direction, a channel structure that penetrates the stacked structure in the vertical direction, a common source line structure that penetrates the stacked structure in the vertical direction, and a second pad connected to the common source line structure,
wherein the common source line structure comprises a central insulating layer, an intermediate conductive layer on a side surface of the central insulating layer, a side insulating layer on a side surface of the intermediate conductive layer, and an upper conductive layer on an upper end of the central insulating layer,
wherein the upper structure contacts the lower structure, and the second pad contacts the first pad.

19. The memory device of claim 18, wherein the upper structure further comprises a lower conductive layer under the stacked structure, and
the intermediate conductive layer is spaced apart from the lower conductive layer by the side insulating layer.

20. The memory device of claim 18, wherein the upper structure further comprises a lower conductive layer under the stacked structure, and
the intermediate conductive layer contacts the lower conductive layer.
